(19) United States
(12) Patent Application Publication
(10) Pub. No.: US 2022/0131045 A1
(43) Pub. Date: Apr. 28, 2022

(54) DISPLAY DEVICE AND METHOD OF FABRICATING DISPLAY DEVICE

(71) Applicant: Samsung Display Co., Ltd., Yongin-si (KR)

(72) Inventors: Chang Hee LEE, Yongin-si (KR); Se Hun KIM, Yongin-si (KR)

(21) Appl. No.: 17/343,392

(22) Filed: Jun. 9, 2021

(30) Foreign Application Priority Data
Oct. 22, 2020 (KR) 10-2020-0137845

(51) Int. Cl. H01L 33/38; H01L 27/15; H01L 33/60; H01L 33/42

(52) U.S. Cl. CPC H01L 33/382; H01L 27/156; H01L 2933/0016; H01L 33/42; H01L 33/60

(57) ABSTRACT

A display device includes a substrate, a first electrode on the substrate, a plurality of light emitting elements on the first electrode, and a second electrode on the plurality of light emitting elements. An area of a first surface of each of the plurality of light emitting elements in contact with the first electrode is different from an area of a second surface of each of the plurality of light emitting elements in contact with the second electrode. Each of the plurality of light emitting elements includes a metal layer in contact with the first electrode and including a fusible alloy or a eutectic alloy.

### CROSS-REFERENCE TO RELATED APPLICATION

This application claims priority to and the benefit of Korean Patent Application No. 10-2020-0137845 filed in the Korean Intellectual Property Office on Oct. 22, 2020, the entire contents of which are hereby incorporated by reference.

### BACKGROUND

### 1. Field

Embodiments of the present disclosure relate to a display device and a method of fabricating the display device.

### 2. Description of the Related Art

With an increasing interest in information displays and an increasing demand for use of portable information media, there are increasing demands and commercialization for display devices.

### SUMMARY

Embodiments of the present disclosure provide a display device capable of increasing light emission efficiency and a method of fabricating the display device.

An embodiment of the present disclosure provides a display device including: a substrate; a first electrode on the substrate; a plurality of light emitting elements on the first electrode; and a second electrode on the plurality of light emitting elements. An area of a first surface of each of the plurality of light emitting elements in contact with the first electrode is different from an area of a second surface of each of the plurality of light emitting elements in contact with the second electrode. Each of the plurality of light emitting elements includes a metal layer in contact with the first electrode and including a fusible alloy and/or a eutectic alloy.

In one or more embodiments, the area of the first surface may be smaller than the area of the second surface, and an area ratio between the first surface and the second surface of each of the plurality of light emitting elements may be 0.25 or more.

In one or more embodiments, a length ratio between a height of each of the plurality of light emitting elements and a length of a longest side of the second surface may be 0.5 or less.

In one or more embodiments, the length of the longest side of the second surface may be approximately 10 nm to approximately 10 μm.

In one or more embodiments, each of the plurality of light emitting elements may have a truncated pyramid shape or a truncated cone shape.

In one or more embodiments, each of the plurality of light emitting elements may further include a first semiconductor layer in contact with the second electrode, a second semiconductor layer in contact with the metal layer, and an active layer between the first semiconductor layer and the second semiconductor layer.

In one or more embodiments, the first semiconductor layer may be an n-type semiconductor layer and the second semiconductor layer may be a p-type semiconductor layer.

In one or more embodiments, each of the plurality of light emitting elements may further include a third semiconductor layer between the first semiconductor layer and the active layer, and a fourth semiconductor layer between the second semiconductor layer and the active layer.

In one or more embodiments, each of the plurality of light emitting elements may further include an insulating film that surrounds an outer peripheral surface of a light emitting stack including the first semiconductor layer, the second semiconductor layer, and the active layer, and exposes the first surface and the second surface.

In one or more embodiments, a melting point of the fusible alloy and/or the eutectic alloy may be approximately 200° C. to approximately 300° C.

In one or more embodiments, the metal layer may include one selected from a group consisting of Field's metal (an alloy including 32.5% of bismuth (Bi), 16.5% of tin (Sn), 51% of indium (In)), Galinstan (an alloy including less than 1.5% of Bi, 9.5 to 10.5% of Sn, 21 to 22% of In, 68 to 69% of gallium (Ga), and less than 1.5% of antimony (Sb)), Cerrolow 136 (an alloy including 49% of Bi, 18% of lead (Pb), 12% of Sn, and 21% of In), Cerrolow 117 (an alloy including 44.7% of Bi, 22.6% of Pb, 8.3% of Sn, 19.1% of In, and 5.3% of cadmium (Cd)), Rose's alloy (an alloy including 50% of Bi, 25% of Pb, and 25% of Sn), Wood's metal (an alloy including 50% of Bi, 26.7% of Pb, 13.3% of Sn, and 10% of Cd), Cerrosafe (an alloy including 42.5% of Bi, 37.7% of Pb, 11.3% of Sn, and 8.5% of Cd), Cerrobend (an alloy including 50% of Bi, 26.7% of Pb, 13.3% of Sn, and 10% of Cd), Lipowitz's alloy (an alloy including 49.5% of Bi, 27.3% of Pb, 13.1% of Sn, and 10.1% of Cd), indium-bismuth alloy (an alloy including 66.3% of In and 33.7% of Bi), ChipQuik desoldering alloy (an alloy including 56% of Bi, 30% of Sn, and 14% of In), Lichtenberg's alloy (an alloy including 50% of Bi, 30% of Pb, and 20% of Sn), an alloy including 52.5% of Bi, 32.0% of Pb, and 15.5% of Sn, Bi 52 (an alloy including 52% of Bi, 32.0% of Pb, and 16% of Sn), Newton's metal (an alloy including 50.0% of Bi, 31.2% of Pb, and 18.8% of Sn), an alloy including 55.5% of Bi and 44.5% of Pb, Bi58 (an alloy including 58% of Bi and 42% of Sn), an alloy including 57% of Bi and 43% of Sn, an alloy including 62.3% of Sn and 37.7% of Pb, Sn63 (an alloy including 63.0% Sn and 37.0% of Pb), KappAloy9 (an alloy including 91.0% of Sn and 9.0% of Zn), and Tin foil (an alloy including 92.0% of Sn and 8.0% of Zn).

In one or more embodiments, the metal layer may further include a magnetic material.

In one or more embodiments, the magnetic material may include a ferromagnetic material and/or a quasi-ferrimagnetic material.

In one or more embodiments, the magnetic material may include permalloy (an alloy including approximately 80% of nickel and 20% of iron), and/or a terbium-iron alloy (Tb—Fe alloy).

In one or more embodiments, the display device may further include an insulating layer that fills a free space between the plurality of light emitting elements and exposes one surface of each of the plurality of light emitting elements in contact with the second electrode.

In one or more embodiments, the insulating layer may include light scattering particles that scatter light emitted from the plurality of light emitting elements.

In one or more embodiments, the insulating layer may include color conversion particles that absorb a light of a first color emitted from the plurality of light emitting elements and emit a light of a second color.

In one or more embodiments, the display device may further include a bank on the substrate to define a light emitting region, and the first electrode and the plurality of light emitting elements may be provided in the light emitting region.

In one or more embodiments, the bank may include a reflective material and increases efficiency of light emitted from the light emitting region.

In one or more embodiments, the display device may further include a light conversion pattern layer on the second electrode to absorb a light emitted from the plurality of light emitting elements and to emit red light or green light.

In one or more embodiments, the display device may further include a color filter under the first electrode.

In one or more embodiments, the first electrode may include a transparent conductive material, and the second electrode may include an opaque metal.

In one or more embodiments, the area of the first surface may be larger than the area of the second surface, and an area ratio between the first surface and the second surface of each of the plurality of light emitting elements may be 4 or less.

In one or more embodiments, a length ratio between a height of each of the plurality of light emitting elements and a length of a longest side of the first surface may be 0.5 or less.

Another embodiment of the present disclosure provides a method of fabricating a display device including: forming a first electrode on a substrate; supplying ink including a plurality of light emitting elements dispersed in a solvent onto the first electrode; aligning the plurality of light emitting elements; and forming a second electrode on the plurality of light emitting elements. An area of a first surface of each of the plurality of light emitting elements in contact with the first electrode is different from an area of a second surface of each of the plurality of light emitting elements in contact with the second electrode. Each of the plurality of light emitting elements includes a metal layer in contact with the first electrode and including a eutectic solder and/or a fusible alloy.

In one or more embodiments, the ink may be supplied onto the first electrode through an inkjet printing technique.

In one or more embodiments, the aligning of the plurality of light emitting elements includes coupling the plurality of light emitting elements to the first electrode by applying a laser light to the metal layer of each of the plurality of light emitting elements.

In one or more embodiments, the aligning of the plurality of light emitting elements may further include aligning the plurality of light emitting elements by applying a magnetic field under the first electrode before the plurality of light emitting elements are coupled to the first electrode, and the metal layer may further include a magnetic material.

In one or more embodiments, the method may further include forming a planarization layer on the first electrode to fill a space between the plurality of light emitting elements before the second electrode is formed.

In one or more embodiments, the forming of the planarization layer on the first electrode may include coating an organic insulating layer on the first electrode, and etching the organic insulating layer to form the planarization layer that exposes the second surfaces of the plurality of light emitting elements.

### BRIEF DESCRIPTION OF THE DRAWINGS

The above and other aspects and features of certain embodiments of the disclosure will be more apparent from the following description taken in conjunction with the accompanying drawings, in which:

FIGS. 1A and 1B are, respectively, a perspective view and a cross-sectional view illustrating a light emitting element according to an embodiment;

FIG. 1C is a cross-sectional view illustrating a light emitting element according to another embodiment;

FIGS. 2A and 2B are, respectively, a perspective view and a cross-sectional view illustrating a light emitting element according to another embodiment;

FIG. 3 is a perspective view illustrating a light emitting element according to another embodiment;

FIGS. 4A and 4B are, respectively, a perspective view and a cross-sectional view illustrating a light emitting element according to another embodiment;

FIG. 5 is a schematic plan view of a display device according to an embodiment of the present disclosure;

FIG. 6 is a circuit diagram illustrating an electrical connection relationship between configuration elements included in one pixel illustrated in FIG. 5, according to an embodiment;

FIG. 7 is a plan view schematically illustrating pixels included in the display device of FIG. 5;

FIG. 8 is a cross-sectional view taken along line I-I′ of the pixel in FIG. 7, according to an embodiment;

FIG. 9 is a cross-sectional view of the pixels in FIG. 7;

FIG. 10 is a cross-sectional view taken along line I-I′ of the pixel in FIG. 7, according to another embodiment;

FIG. 11 is a cross-sectional view taken along line I-I′ of the pixel in FIG. 7, according to another embodiment; and

FIGS. 12 to 17 are schematic cross-sectional views illustrating a method of fabricating a display device according to an embodiment of the present disclosure.

### DETAILED DESCRIPTION

Because the subject matter of the present disclosure may be variously modified and may have various forms, example embodiments will be illustrated in the drawings and described in more detail in the specification. However, this is not intended to limit the present disclosure to a specific disclosure form and should be understood to include all changes, equivalents, and substitutes included in the spirit and scope of the present disclosure.

In describing the respective drawings, similar reference numerals are given to similar configuration elements. In the drawings, dimensions of structures may be enlarged more than actual structures for the sake of clear illustration of the subject matter of the present disclosure. Terms, “first” and “second”, may be used to describe various configuration elements, and the configuration elements are not limited thereto. The terms are used only for the purpose of distinguishing one configuration element from another configuration element. For example, a first configuration element may be referred to as a second element, and similarly, a second element may be referred to as a first element, without departing from the scope of the present disclosure. A singular expression includes a plural expression unless the context clearly indicates otherwise.

In the present application, the terms, “comprise” and “have” are intended to designate presence of characteristics, numbers, steps, actions, configuration elements, components, or combinations thereof described in the specification, and it should be understood that the possibility of the presence or addition of one or more other characteristics, numbers, steps, actions, configuration elements, components, or combinations thereof are not excluded. In addition, when a portion such as a layer, film, region, or plate is described as being placed “on” another portion, this includes not only a case in which the portion is “directly on” another portion but also a case in which another portion is therebetween. In addition, in the present specification, when a portion such as a layer, film, region, or plate is formed on another portion, the formed direction is not limited only to an upper direction and includes a lateral direction or a lower direction. In contrast to this, when a portion such as layer, film, region, or plate is described as being placed “below” another portion, this includes not only a case in which the portion is “directly below” another portion but also a case in which another portion is therebetween.

In the present application, when it is described that a certain configuration element (for example, a “first configuration element”) is “connected (operatively or communicatively)” or “coupled” to another configuration element (for example, a “second configuration element”), it should be understood that the certain configuration element may be directly connected to or coupled to another configuration element or may be connected or coupled through another configuration element (for example, a “third configuration element”). In contrast to this, when it is described that a certain configuration element (for example, a “first configuration element”) is “directly connected” or “directly coupled” to another configuration element (for example, a “second configuration element”), it may be understood that there is no configuration element (for example, a “third configuration element”) therebetween.

Hereinafter, embodiments of the present disclosure and other matters helpful for those skilled in the art to easily understand the content of the present disclosure will be described in more detail with reference to the accompanying drawings. In the following description, a singular expression also includes a plural expression unless the context clearly includes only the singular expression.

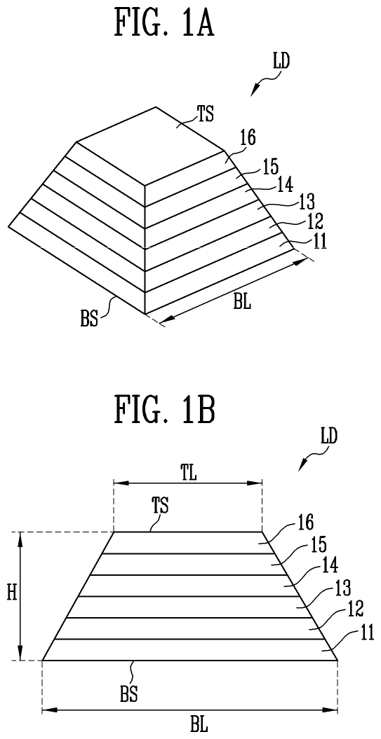

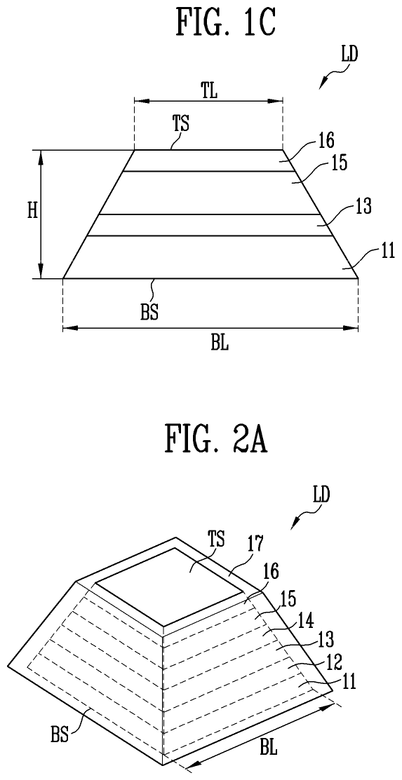

FIGS. 1A and 1B are, respectively, a perspective view and a cross-sectional view illustrating a light emitting element according to an embodiment. FIG. 1C is a cross-sectional view illustrating a light emitting element according to another embodiment.

Referring to FIGS. 1A, 1B, and 1C, a light emitting element LD may be formed in a truncated pyramid shape, but the present disclosure is not limited thereto. An area of an upper surface TS (or a first surface) of the light emitting element LD differs from an area of a lower surface BS (or a second surface) thereof, and, for example, the area of the upper surface TS of the light emitting element LD may be smaller than the area of the lower surface BS.

In one or more embodiments, an area ratio between the upper surface TS and the lower surface BS of the light emitting element LD may be 0.25 or more, and a length ratio between a height H (or a thickness) of the light emitting element LD and a length BL of the longest sides of the lower surface BS may be 0.5 or less. Here, the area ratio may be defined as a ratio (e.g., TS/BS) of the area of the upper surface TS with respect to the area of the lower surface BS of the light emitting element LD, and the length ratio is may be defined as a ratio (e.g., H/BL) of the height H with respect to the length BL of the longest side of the lower surface BS of the light emitting element LD. The area ratio between the upper surface TS and the lower surface BS may be less than 1 depending on a shape of the light emitting element LD. A length ratio between the length TL of the longest side of the upper surface TS of the light emitting element LD and the length BL of the longest side of the lower surface BS may be 0.5 or more.

In this case, as will be further described below with reference to FIG. 13, when the light emitting element LD is provided on the substrate, the light emitting element LD may be on the substrate so that the upper surface TS (or the lower surface BS) of the light emitting element LD faces the substrate. When the area ratio between the upper surface TS and the lower surface BS of the light emitting element LD is less than 0.25, and when the length ratio between the height H of the light emitting element LD and the length BL of the longest side of the lower surface BS is greater than 0.5, an area of one side of the light emitting element LD may be greater than an area of the upper surface TS, and a side surface (or an inclined surface) of the light emitting element LD may face the substrate, resulting in incorrect or undesirable arrangement of the light emitting element LD on the substrate. Even when the area ratio between the upper surface TS and the lower surface BS of the light emitting element LD is 1, the side surface of the light emitting element LD may face the substrate, resulting in incorrect or undesirable arrangement of the light emitting element LD on the substrate.

The light emitting element LD may include a light emitting diode (LED) fabricated in a small size to have the height H or the length BL of, for example, approximately a nano scale to a micro scale (e.g., in a range of nanometers to micrometers). For example, the length BL of the longest side of the lower surface BS of the light emitting element LD may be approximately 10 nm to approximately 10 μm. However, the length L of the light emitting element LD is not limited thereto, and the light emitting element LD may be changed in size so as to meet requirements (or design conditions) of an illumination device and/or a self-luminous display device to which the light emitting element LD is applied.

The light emitting element LD may include a first semiconductor layer 11, a second semiconductor layer 15, an active layer 13 between the first semiconductor layer 13 and the second semiconductor layer 15, and a metal layer 16 on the second semiconductor layer 15. For example, the light emitting element LD may include a light emitting stack in which the first semiconductor layer 11, the active layer 13, the second semiconductor layer 15, and the metal layer 16 are sequentially stacked. In addition, as illustrated in FIGS. 1A and 1B, the light emitting element LD may further include a third semiconductor layer 12 between the first semiconductor layer 11 and the active layer 13, and the fourth semiconductor layer 14 between the second semiconductor layer 15 and the active layer 13.

The light emitting element LD may include one end (or a lower end) and the other end (or an upper end) in the height H direction of the light emitting element LD. The first semiconductor layer 11 may be at one end of the light emitting element LD, and the metal layer 16 may be at the other end of the light emitting element LD.

The first semiconductor layer 11 may include, for example, at least one n-type semiconductor layer. For example, the first semiconductor layer 11 includes any one of InAlGaN, GaN, AlGaN, InGaN, AlN, and/or InN, and may be an n-type semiconductor layer doped with a first conductive dopant (or n-type dopant) such as Si, Ge, Sn, and/or the like. However, the material forming the first semiconductor layer 11 is not limited thereto, and the first semiconductor layer 11 may be formed of various other suitable materials. In one embodiment of the present disclosure, the first semiconductor layer 11 may include a gallium nitride (GaN) semiconductor material doped with a first conductive dopant (or n-type dopant). The first semiconductor layer 11 may include a lower surface (e.g., a lower surface BS) exposed to the outside in the height H direction of the light emitting element LD, and the lower surface of the first semiconductor layer 11 may be one end of the light emitting element LD.

The active layer 13 may be over the first semiconductor layer 11 and may be formed in a single structure or a multi-quantum well structure. For example, when the active layer 13 is formed in a multi-quantum well structure, the active layer 13 may have a structure in which one unit configured by a barrier layer, a strain reinforcing layer, and a well layer is stacked repeatedly and periodically. The strain reinforcing layer may have a smaller lattice constant than the barrier layer, thereby further reinforcing strain, for example, compression strain applied to the well layer. However, a structure of the active layer 13 is not limited to the above-described embodiment.

The active layer 13 may emit light having a wavelength of 400 nm to 900 nm and may use a double hetero structure.

When an electric field of a set or predetermined voltage or more is applied to both ends of the light emitting element LD, a pair of electron and hole are coupled in the active layer 13 to cause the light emitting element LD to emit light. By controlling light emission of the light emitting element LD by using this principle, the light emitting element LD may be used as a light source (or light emitting source) for various suitable light emitting devices including pixels of a display device.

The third semiconductor layer 12 may be under the active layer 13 in the height H direction of the light emitting element LD. For example, the third semiconductor layer 12 may be between the active layer 13 and the first semiconductor layer 11. The fourth semiconductor layer 14 may be on the active layer 13 in the height H direction of the light emitting element LD. For example, the fourth semiconductor layer 14 may be between the active layer 13 and the second semiconductor layer 15. Each of the third semiconductor layer 12 and the fourth semiconductor layer 14 may include a clad layer doped with a conductive dopant and/or a tensile strain barrier reducing (TSBR) layer. The TSBR layer may be a strain buffer layer that is between semiconductor layers having different lattice structures and serves as a buffer for reducing a difference in lattice constant. For example, each of the third semiconductor layer 12 and the fourth semiconductor layer 14 may be composed of an AlGaN layer and/or an InAlGaN layer but is not limited thereto. In some embodiment, as illustrated in FIG. 1C, the third and fourth semiconductor layers 12 and 14 may be omitted, or the third and fourth semiconductor layers 12 and 14 may also be included in the first and second semiconductor layers 11 and 15 or the active layer 13.

The second semiconductor layer 15 may be over the active layer 13 and may include a semiconductor layer of a different type or kind from the first semiconductor layer 11. For example, the second semiconductor layer 15 may include at least one p-type semiconductor layer. For example, the second semiconductor layer 15 may include at least one of InAlGaN, GaN, AlGaN, InGaN, AlN, and/or InN, and/or may include a p-type semiconductor layer doped with a second conductive dopant (or p-type dopant) such as Mg. However, a material forming the second semiconductor layer 15 is not limited thereto, and various other suitable materials may form the second semiconductor layer 15. In one embodiment of the present disclosure, the second semiconductor layer 15 may include a gallium nitride (GaN) semiconductor material doped with a second conductive dopant (or p-type dopant).

In one embodiment, the first semiconductor layer 11 and the second semiconductor layer 15 may have different thicknesses and/or different volumes in the height H direction of the light emitting element LD. For example, the first semiconductor layer 11 may have a relatively greater thickness and/or a relatively greater volume than the second semiconductor layer 15 in the height H direction of the light emitting element LD. In some embodiments, the active layer 13 of the light emitting element LD may be located closer to the second semiconductor layer 15 than the first semiconductor layer 11.

The metal layer 16 may be on the second semiconductor layer 15. The metal layer 16 may be an ohmic contact electrode, but the present disclosure is not limited thereto. In some embodiments, the metal layer 16 may be a Schottky contact electrode. The metal layer 16 may include a conductive material (e.g., an electrically conductive material). For example, the metal layer 16 may be an opaque metal in which chromium (Cr), titanium (Ti), aluminum (Al), gold (Au), nickel (Ni), an oxide thereof, and/or an alloy thereof are used alone or in combination, but the present disclosure is not limited thereto. In some embodiments, the metal layer 16 may include a transparent conductive oxide such as indium tin oxide (ITO), indium zinc oxide (IZO), zinc oxide (ZnO), indium gallium zinc oxide (IGZO), and/or indium tin zinc oxide (ITZO).

The metal layer 16 may include an upper surface (e.g., the upper surface TS) exposed to the outside in the height H direction of the light emitting element LD, and the upper surface of the metal layer 16 may become the other end of the light emitting element LD.

In one or more embodiments, the metal layer 16 may include a fusible alloy and/or a eutectic alloy.

The fusible alloy and/or the eutectic alloy may be a metal or alloy having a melting point of 300° C. or less, and for example, the melting point of the fusible alloy and/or the eutectic alloy may be approximately 200° C. to approximately 300° C.

The fusible alloy or the eutectic alloy may be one selected from a group, consist of Field's metal (bismuth (Bi) 32.5%, Sn 16.5%, In 51%), Galinstan (Bi<1.5%, tin (Sn) 9.5-10.5%, indium (In) 21-22%, gallium (Ga) 68-69%, and antimony (Sb) <1.5%), Cerrolow 136 (Bi 49%, lead (Pb) 18%, Sn 12%, and In 21%), Cerrolow 117 (Bi 44.7%, Pb 22.6%, Sn 8.3%, In 19.1%, and cadmium (Cd) 5.3%), Rose's alloy (Bi 50%, Pb 25%, and Sn 25%), Wood's metal (Bi 50%, Pb 26.7%, Sn 13.3%, and Cd 10%), Cerrosafe (Bi 42.5%, Pb 37.7%, Sn 11.3%, and Cd 8.5%), Cerrobend (Bi 50%, Pb 26.7%, Sn 13.3%, and Cd 10%), Lipowitz's alloy (Bi 49.5%, Pb 27.3%, Sn 13.1%, and Cd 10.1%), indium-bismuth alloy (In 66.3% and Bi 33.7%), ChipQuik desoldering alloy (Bi 56%, Sn 30%, and In 14%), Lichtenberg's alloy (Bi 50%, Pb 30%, and Sn 20%), “Bi 52.5%, Pb 32.0%, and Sn 15.5%”, Bi 52 (Bi 52%, Pb 32.0%, and Sn 16%), Newton's metal (Bi 50.0%, Pb 31.2%, and Sn 18.8%), “Bi 55.5% and Pb 44.5%”, Bi58 (Bi 58% and Sn 42%), “Bi 57% and Sn 43%”, “Sn 62.3% and Pb 37.7%”, Sn63 (Sn 63.0% and Pb 37.0%), KappAloy9 (Sn 91.0% and Zn 9.0%), and Tin foil (Sn 92.0% and Zn 8.0%). For example, the metal layer 16 may include a eutectic solder of Sn63 (Sn 63.0% and Pb 37.0%), which has the lowest melting point among tin-lead alloys.

As will be described below with reference to FIG. 14, after the light emitting element LD is supplied on the substrate, a laser light (and/or heat) may be applied to the metal layer 16 of the light emitting element LD, and thereby, the light emitting element LD may be coupled to or connected to a lower structure (for example, a pixel electrode).

In one or more embodiments, the metal layer 16 may include a ferromagnetic material and/or a quasi-ferromagnetic material. The ferromagnetic material and/or the quasi-ferromagnetic material forms a separate layer and may be inserted or arranged between a fusible alloy and/or a eutectic alloy and another layer (for example, the second semiconductor layer 15). In other embodiments, the ferromagnetic material and/or the quasi-ferromagnetic material may be coated on the fusible alloy and/or the eutectic alloy.

The ferromagnetic material and/or quasi-ferromagnetic material may include iron, nickel, cobalt, and/or the like. For example, the ferromagnetic material may include permalloy (alloy of nickel of approximately 80% and iron of 20%) that is easy to process, and the quasi-ferromagnetic material may include a terbium-iron alloy (Tb—Fe alloy).

As will be described below with reference to FIG. 13, when the light emitting element LD is supplied onto the substrate, the ferromagnetic material and/or the quasi-ferromagnetic material is attracted by an electromagnet (or a magnetic field formed by the electromagnet) under the substrate to arrange the light emitting element LD on the substrate so that the upper surface TS of the light emitting element LD, not the other side of the metal layer 16 (e.g., the light emitting element LD), faces the substrate.

The light emitting element LD may be used as a light emitting source (or light source) for various suitable display devices. The light emitting element LD may be fabricated through a surface treatment process. For example, when a plurality of light emitting elements LD are mixed with a fluid solution (or solvent) and supplied to each substrate (or a pixel region, for example, a light emitting region of ach pixel or a light emitting region of each sub-pixel), each of the light emitting elements LD may be subjected to surface treatment so that the light emitting elements LD may be uniformly (e.g., substantially uniformly) sprayed without (or substantially without) uneven aggregation in the solution.

A light emitting unit (or a light emitting device) including the light emitting elements LD may be used for various suitable types or kinds of electronic devices that require a light source, including a display device. For example, when a plurality of light emitting elements LD are in a pixel region of each pixel of a display panel, the light emitting elements LD may be used as a light source of each pixel. However, a field of application of the light emitting element LD is not limited to the above-described example. For example, the light emitting element LD may also be used for other types or kinds of electronic devices that require a light source such as an illumination device.

As described above, the light emitting element LD may have a pyramid shape (e.g., a truncated pyramidal shape). In addition, the light emitting element LD may further include the metal layer 16 on the second semiconductor layer 15, and the metal layer 16 may include a fusible alloy and/or a eutectic alloy, and a ferromagnetic material and/or a quasi-ferromagnetic material. Therefore, when the light emitting element LD is supplied on the substrate, the light emitting element LD may be on a substrate so that the metal layer 16 of the light emitting element LD faces the substrate by the pyramidal shape of the light emitting element LD and also by aid of the ferromagnetic material and/or the quasi-ferromagnetic material. For example, the light emitting element LD may be arranged or aligned in a suitable or desired position on the substrate, and thus, misarrangement (or misalignment) of the light emitting element LD may be prevented or reduced.

In one or more embodiments, although FIGS. 1A to 1C illustrate that the light emitting element LD has a quadrangular pyramid shape, for example, a rectangular shape in a plan view, this is an example, and the light emitting element LD is not limited thereto. For example, the light emitting element LD may have a shape in a plan view such as a triangle, a polygon of a pentagon or more, a circle, or an ellipse.

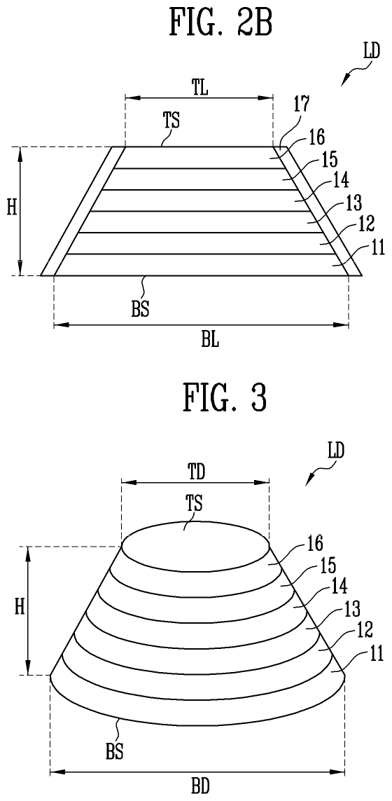

FIGS. 2A and 2B are respectively a perspective view and a cross-sectional view of a light emitting element according to another embodiment.

Referring to FIGS. 1A, 1B, 2A, and 2B, the light emitting element LD may further include an insulating film 17.

The insulating film 17 may be formed to entirely surround an outer peripheral surface (e.g., an outer circumferential surface or a side surface or an inclined surface) of the light emitting stack including the first semiconductor layer 11, the active layer 13, and the second semiconductor layer 15. The insulating film 17 may expose the upper surface TS and the lower surface BS of the light emitting element LD.

In the above-described embodiment, it is described that the insulating film 17 surrounds an entire side surface of each of the first semiconductor layer 11, the active layer 13, and the second semiconductor layer 15, but the present disclosure is limited thereto. In some embodiments, the insulating film 17 may also surround a side surface of the metal layer 16. In addition, according to another embodiment, the insulating film 17 may not surround the entire side surface of the metal layer 16 or may surround part (for example, part of a lower side) of the side surface of the metal layer 16 and may not surround the rest (for example, part of an upper side) of the side surface of the metal layer 16.

The insulating film 17 may prevent or reduce occurrence of an electrical short circuit when the active layer 13 comes into contact with a conductive material other than the first and second semiconductor layers 11 and 15. In addition, the insulating film 17 may minimize or reduce surface defects of the light emitting element LD, thereby increasing lifetime and light emission efficiency of the light emitting element LD. In addition, when a plurality of light emitting elements LD are closely arranged, the insulating film 17 may prevent or reduce occurrence of unwanted short circuits between the light emitting elements LD. If the active layer 13 may prevent or reduce occurrence of a short circuit with an external conductive material (e.g., an electrically conductive material), whether or not to form the insulating film 17 is not limited.

The insulating film 17 may include a transparent insulating material (e.g., a transparent, electrically insulating material). For example, the insulating film 17 may include at least one insulating material selected from a group consisting of silicon oxide (SiOx), silicon nitride (SiNx), silicon oxynitride (SiOxNy), aluminum oxide (AlOx), and titanium oxide (TiOx), but the present disclosure is not limited thereto, and various suitable materials having insulation properties (e.g., electrically insulating properties) may be used as the material of the insulating film 17.

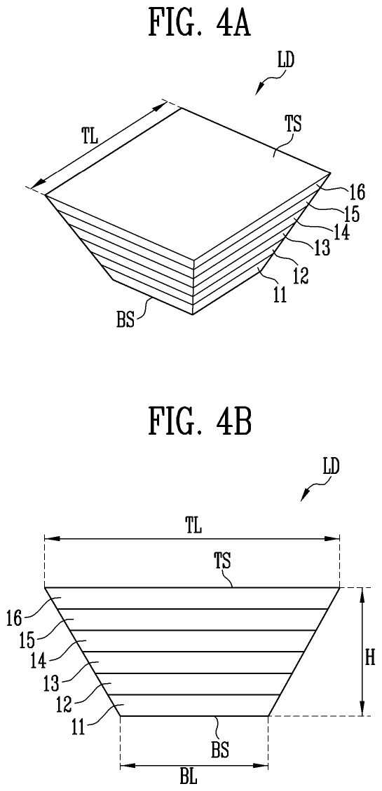

FIG. 3 is a perspective view illustrating a light emitting element according to another embodiment.

Referring to FIGS. 1A, 1B, and 3, the light emitting element LD may have a truncated cone shape. As described with reference to FIGS. 1A and 1B, an area of the upper surface TS (or the first surface) of the light emitting element LD differs from an area of the lower surface BS (or the second surface), and for example, an area of the upper surface TS of the light emitting element LD may be smaller than an area of the lower surface BS.

In one or more embodiments, an area ratio between the upper surface TS and the lower surface BS of the light emitting element LD is 0.25 or more, and a length ratio between the height H (or thickness) of the light emitting element LD and a diameter BD of the lower surface BS may be 0.5 or less. Here, the length ratio may be defined as a ratio of the height H with respect to the diameter BD of the lower surface BS of the light emitting element LD (e.g., H/BD). According to the shape of the light emitting element LD, the area ratio between the upper surface TS and the lower surface BS may be less than 1. A length ratio between the diameter TD of the upper surface TS of the light emitting element LD and the diameter BD of the lower surface BS may be 0.5 or more. For example, the diameter BD of the lower surface BS of the light emitting element LD may be approximately 10 nm to approximately 10 μm.

The light emitting element LD may include a first semiconductor layer 11, a second semiconductor layer 15, an active layer 13 between the first semiconductor layer 11 and the second semiconductor layer 15, and a metal layer 16 on the second semiconductor layer 15. A stack structure of the light emitting element LD is substantially the same as or similar to the stack structure of the light emitting element LD described with reference to FIGS. 1A to 2B, and thus, description of the stack structure of the light emitting element LD illustrated in FIG. 3 will not be repeated.

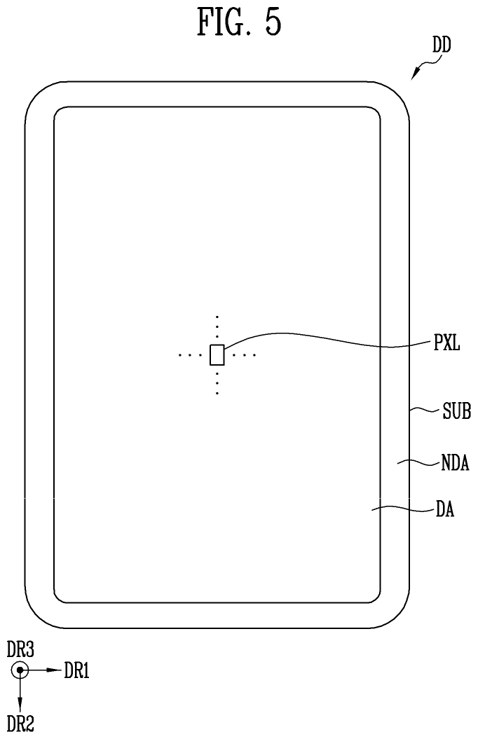

FIGS. 4A and 4B are respectively a perspective view and a cross-sectional view of a light emitting element according to another embodiment.

Referring to FIGS. 1A, 1B, 4A, and 4B, an area of an upper surface TS of the light emitting element LD may also be greater than an area of a lower surface BS.

In one or more embodiments, an area ratio between the upper surface TS and the lower surface BS of the light emitting element LD is 4 or less, and a length ratio between a height H (or thickness) of the light emitting element LD and a length TL of the longest side of the upper surface TS may be 0.5 or less. Here, the area ratio may be defined as a ratio of the area of the upper surface TS with respect to the area of the lower surface BS of the light emitting element LD (e.g., TS/BS), and the length ratio may be defined as a ratio of the height H with respect to the length TL of the longest side of the upper surface TS (e.g., H/TL). A length ratio between the length TL of the longest side of the upper surface TS of the light emitting element LD and the length BL of the longest side of the lower surface BS may be 2 or less.

In one or more embodiments, when the first semiconductor layer 11 constitutes the lower surface BS of the light emitting element LD and the metal layer 16 constitutes the upper surface TS of the light emitting element LD, the light emitting element LD may be formed in a shape of an inverted truncated pyramid.

The light emitting element LD includes a first semiconductor layer 11, a second semiconductor layer 15, an active layer 13 between the first second semiconductor layer 11 and the second semiconductor layer 15, and a metal layer 16 on the second semiconductor layer 15. A stack structure of the light emitting element LD is substantially the same as or similar to the stack structure of the light emitting element LD described with reference to FIGS. 1A to 2B, and thus, redundant description of the stack structure of the light emitting element LD illustrated in FIGS. 4A and 4B will not be repeated here.

Compared to the light emitting element LD of FIGS. 1A to 3, the metal layer 16 of the light emitting element LD of FIGS. 4A and 4B may have a relatively large area. In this case, when the light emitting element LD is supplied on the substrate, a ferromagnetic material and/or a quasi-ferromagnetic material included in the metal layer 16 may help more to arrange the light emitting elements LD on the substrate SUB so that metal layer 16 (e.g., the upper surface TS of the light emitting element LD other than the other side thereof) faces the substrate. Accordingly, the light emitting element LD may be arranged or aligned in a suitable or desired position on the substrate, and misarrangement (or misalignment) of the light emitting element LD may be prevented or reduced.

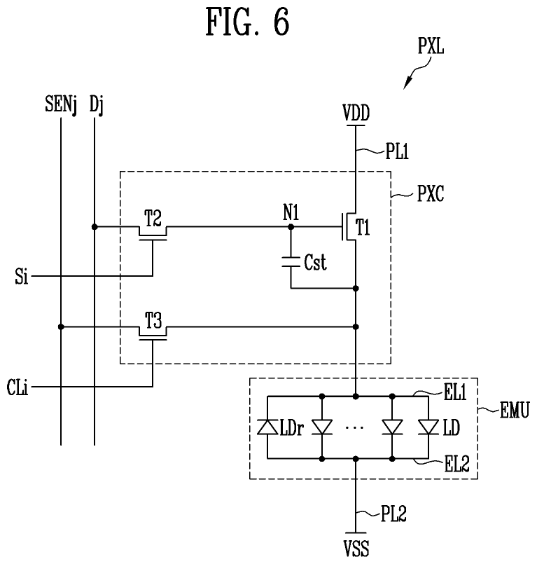

FIG. 5 is a schematic plan view of a display device DD according to an embodiment of the present disclosure that uses the light emitting element LD illustrated in FIGS. 1A to 4B as a light source. In FIG. 5, for the sake of convenience, a structure of the display device DD is schematically illustrated centering on a display region DA where an image is displayed.

Referring to FIGS. 1A to 5, the display device DD may include a substrate SUB, a plurality of pixels PXL that are provided on the substrate SUB and each include at least one light emitting element LD, a drive portion that is provided on the substrate SUB and drives the pixels PXL, and a wiring portion that couples the pixels PXL to the drive portion.

If the display device (DD) is an electronic device having a display surface applied to at least one surface, such as a smartphone, television, tablet personal computer (PC), mobile phone, video phone, e-book reader, desktop PC, laptop PC, netbook computer, workstation, server, personal digital assistant (PDA), portable multimedia player (PMP), moving pictures experts group (MPEG) audio layer-3 (MP3) player, medical device, camera, and/or a wearable device, the present disclosure may be applied thereto.

The display device DD may be divided into a passive matrix type or kind of display device and an active matrix type or kind of display device according to a method of driving the light emitting element LD. For example, when the display device DD is an active matrix type or kind of display device, each of the pixels PXL may include a drive transistor that controls a current supplied to the light emitting element LD, a switching transistor that transmits a data signal to the drive transistor, and so on.

The display device DD may be provided in various suitable shapes, for example, a rectangular plate shape having two pairs of sides parallel (e.g., substantially parallel) to each other, but the present disclosure is not limited thereto. When the display device DD is provided in a rectangular plate shape, one of the two pairs of sides may be longer than the other pair of sides. For the sake of convenience, a case in which the display device DD has a rectangular shape having a pair of long sides and a pair of short sides is illustrated, and an extension direction of the long sides is referred to as a second direction DR2, an extension direction of the short sides is referred to as a first direction DR1 is, and a direction perpendicular (e.g., substantially perpendicular) to the extension direction of the long sides and the short sides is referred to as a third direction DR3. In some embodiment, the display device DD provided in a rectangular plate shape may also have a corner portion having a round shape in which one long side and one short side are in contact (or meet) with each other.

The substrate SUB may include the display region DA and a non-display region NDA.

The display region DA may be a region in which pixels PXL for displaying an image are provided. The non-display region NDA may be a region in which a drive portion for driving the pixels PXL and part of a wiring portion for coupling the pixels PXL to the drive portion are provided. For the sake of convenience, only one of the pixels PXL is illustrated in FIG. 5, but the present disclosure is not limited thereto. For example, a plurality of pixels PXL may be provided in the display region DA of the substrate SUB.

The non-display region NDA may be provided on at least one side of the display region DA. The non-display region NDA may surround a periphery (e.g., a circumference or edge) of the display region DA. The non-display region NDA may include a wiring portion coupled to the pixels PXL and a drive portion that is coupled to the wiring portion and drives the pixels PXL. However, the present disclosure is not limited thereto, and the non-display region NDA may be omitted, and in this case, the drive portion may be provided in the display region DA, for example, may also be dispersedly provided between the pixels PXL.

The wiring portion may electrically couple the drive portion to the pixels PXL. The wiring portion may be a fan-out line that provides a signal to the pixels PXL and is coupled to signal lines, for example, a scan line, a data line, a light emission control line, and/or the like which are coupled to the pixels PXL. In addition, the wiring portion is a fan-out line that is coupled to signal lines, for example, a control line, a sensing line, and/or the like, which are coupled to the pixels PXL, to compensate for a change in electrical characteristics of each pixel PXL in real time.

The substrate SUB may include a transparent insulating material (e.g., a transparent, electrically conductive material) to allow light to pass therethrough. The substrate SUB may be a rigid substrate and/or a flexible substrate.

One region on the substrate SUB may be provided as the display region DA so that the pixels PXL are arranged, and the other region on the substrate SUB may be provided as the non-display region NDA.

The pixels PXL may be provided in the display region DA on the substrate SUB. In one embodiment of the present disclosure, the pixels PXL may be in the display region DA in a stripe arrangement structure or a PENTILE® arrangement structure (e.g., an RGBG matrix, RGBG structure, or RGBG matrix structure), but the present disclosure is not limited thereto. PENTILE® is a duly registered trademark of Samsung Display Co., Ltd.

Each of the pixels PXL may include at least one light emitting element LD driven by a corresponding scan signal and a data signal. The light emitting element LD may have a size as small as a microscale or a nanoscale (e.g., in a range of nanometers or micrometers) and may be coupled in parallel to the light emitting elements LD adjacent to each other, but the present disclosure is not limited thereto. The light emitting element LD may also constitute a light source of each of the pixels PXL.

Each of the pixels PXL may include at least one light source, which is driven by a set or predetermined signal (for example, a scan signal and a data signal) and/or a set or predetermined power supply (for example, a first drive power supply and a second drive power supply), for example, the light emitting element LD illustrated in FIGS. 1A to 4B. However, the type or kind of the light emitting element LD that may be used as a light source of each of the pixels PXL in embodiments of the present disclosure is not limited thereto.

The drive portion may provide a set or predetermined signal and a set or predetermined power supply voltage to each of the pixels PXL through the wiring portion, thereby control the drive of the pixels PXL. The drive portion may include a scan drive portion, a data drive portion, and a timing controller.

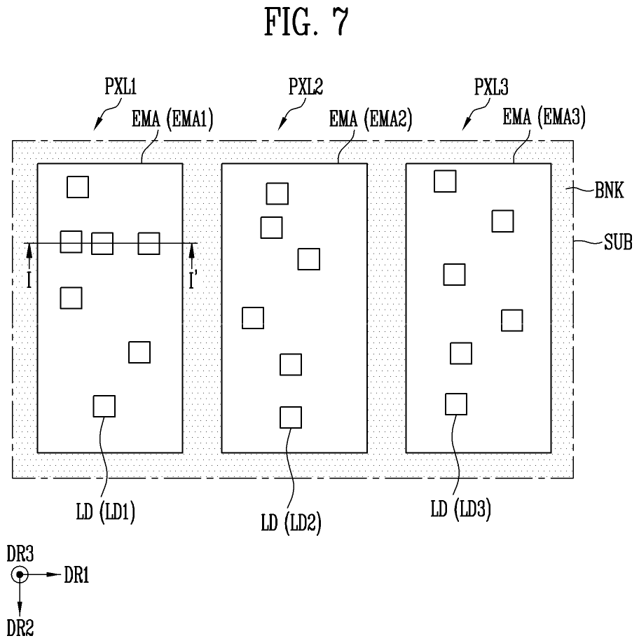

FIG. 6 is a circuit diagram illustrating an electrical connection relationship between configuration elements included in one pixel illustrated in FIG. 5, according to an embodiment.

For example, FIG. 6 illustrates an electrical connection relationship between configuration elements included in the pixel PXL that may be applied to an active display device, according to an embodiment. However, the type or kind of the configuration elements included in the pixel PXL to which embodiments of the present disclosure may be applied is not limited thereto.

In FIG. 6, not only the configuration elements included in the pixel PXL illustrated in FIG. 5 but also a region in which the configuration elements are provided are referred to as the pixel PXL.

Referring to FIGS. 5 and 6, one pixel PXL (hereinafter referred to as a “pixel”) may include a light emitting unit EMU that generates light with a luminance corresponding to a data signal. In addition, the pixel PXL may selectively further include a pixel circuit PXC for driving the light emitting unit EMU.

In some embodiments, the light emitting unit EMU may include a plurality of light emitting elements LD coupled in parallel between a first power line PL1 to which a voltage of a first drive power supply VDD is applied and a second power line PL2 to which a voltage of a second drive power supply VSS is applied. For example, the light emitting unit EMU may include a first electrode EL1 coupled to the first drive power supply VDD through the pixel circuit PXC and the first power line PL1, a second electrode EL2 coupled to the second drive power supply VSS through the second power line PL2, and the plurality of light emitting elements LD coupled in parallel between the first electrode EL1 and the second electrodes EL2 in the same (e.g., substantially the same) direction. In one embodiment of the present disclosure, the first electrode EL1 may be an anode, and the second electrode EL2 may be a cathode.

Each of the light emitting elements LD included in the light emitting unit EMU may include one end coupled to the first drive power supply VDD through the first electrode EL1 and the other end coupled to the second drive power supply VSS through the second electrode EL2. The first drive power supply VDD and the second drive power supply VSS may have different potentials. For example, the first drive power supply VDD may be set as a high potential power supply, and the second drive power supply VSS may be set as a low potential power supply. In this case, a potential difference between the first and second drive power supplies VDD and VSS may be set to be greater than or equal to a threshold voltage of the light emitting elements LD during a light emitting period of the pixel PXL.

As described above, each of the light emitting elements LD coupled in parallel in the same (e.g., substantially the same) direction (for example, forward direction) between the first electrode EL1 and the second electrode EL2 to which voltages of different potentials are respectively supplied may constitute each of effective light sources. The effective light sources may constitute the light emitting unit EMU of the pixel PXL.

The light emitting elements LD of the light emitting unit EMU may emit light with luminance corresponding to a drive current supplied through the pixel circuit PXC. For example, during each frame period, the pixel circuit PXC may supply a drive current corresponding to a gray level value of the corresponding frame data to the light emitting unit EMU. The drive current supplied to the light emitting unit EMU may be divided and flow into each of the light emitting elements LD. Accordingly, while each of the light emitting elements LD emits light with luminance corresponding to a current flowing therethrough, the light emitting unit EMU may emit light of luminance corresponding to the drive current.

An embodiment in which both ends of the light emitting elements LD are coupled in the same (e.g., substantially the same) direction between the first drive power supply VDD and the second drive power supply VSS is illustrated, but the present disclosure is not limited thereto. In some embodiments, the light emitting unit EMU may further include at least one non-effective light source, for example, a reverse light emitting element LDr, in addition to the light emitting elements LD constituting each effective light source. The reverse light emitting element LDr may be coupled in parallel between the first electrode EL1 and the second electrode EL2 together with the light emitting elements LD constituting the effective light sources, and may be coupled between the first electrode EL1 and the second electrode EL2 in an opposite direction to the light emitting elements LD. The reverse light emitting element LDr maintains an inactive state even when a set or predetermined drive voltage (for example, a forward drive voltage) is applied between the first electrode EL1 and the second electrode EL2, and thereby, a current does not substantially flow through the light emitting element LDr.

The pixel circuit PXC may be coupled to a scan line Si and a data line Dj of the pixel PXL. For example, when the pixel PXL is in an i^{th} (i is a natural number) row and a j^{th} (j is a natural number) column of the display region DA, the pixel circuit PXC of the pixel PXL may be coupled to the i^{th} scan line Si and the j^{th} data line Dj of the display region DA. In addition, the pixel circuit PXC may be coupled to an i-^{h} control line CLi and a j^{th} sensing line SENj of the display region DA.

The pixel circuit PXC described above may include a first transistor T1 to a third transistor T3 and a storage capacitor Cst.

A first terminal of the first transistor T1 (drive transistor) may be coupled to a first drive power supply VDD, and a second terminal thereof may be electrically coupled to a first electrode EL1 of each of the light emitting elements LD. A gate electrode of the first transistor T1 may be coupled to the first node N1. The first transistor T1 may control a drive current supplied to the light emitting elements LD in response to a voltage of the first node N1.

A first terminal of a second transistor T2 (switching transistor) may be coupled to the j^{th} data line Dj, and a second terminal thereof may be coupled to a first node N1. Here, the first terminal and the second terminal of the second transistor T2 may be different from each other, and for example, if the first terminal is a source electrode, the second terminal may be a drain electrode. In addition, a gate electrode of the second transistor T2 may be coupled to the i^{th} scan line Si.

The second transistor T2 is turned on when a scan signal having a voltage by which the second transistor T2 may be turned on is supplied from the i^{t}h scan line Si, and thereby, the j^{th} data line Dj and the first node N1 are electrically coupled to each other. In this case, a data signal of a corresponding frame is supplied to the j^{th} data line Dj, and accordingly, the data signal is transmitted to the first node N1. The data signal transmitted to the first node N1 is charged in the storage capacitor Cst.

The third transistor T3 may be coupled between the first transistor T1 and the j^{th} sensing line SENj. For example, a first terminal of the third transistor T3 may be coupled to the second terminal (for example, the source electrode) of the first transistor T1 coupled to the first electrode EL1, and a second terminal of the third transistor T3 may be coupled to the j^{th} sensing line SENj. A gate electrode of the third transistor T3 may be coupled to the i^{th} control line CLi. The third transistor T3 is turned on by a control signal having a gate-on voltage supplied to the i^{th} control line CLi during a set or predetermined sensing period, and thereby, the j^{th} sensing line SENj and the first transistor T1 are electrically coupled to each other.

The sensing period may be a period in which characteristic information (for example, a threshold voltage of the first transistor T1 and/or the like) of each of the pixels PXL in the display region DA is extracted.

One electrode of the storage capacitor Cst may be coupled to the first node N1, and the other electrode of the storage capacitor Cst may be coupled to the second terminal of the first transistor T1 coupled to the first electrode EL1. The storage capacitor Cst may charge a voltage corresponding to a data signal supplied to the first node N1 and maintain the charged voltage until a data signal of the next frame is supplied.

FIG. 6 illustrates an embodiment in which all of the first to third transistors T1 to T3 are N-type transistors, but the present disclosure is not limited thereto. For example, at least one of the first to third transistors T1 to T3 described above may also be changed to a P-type transistor. In addition, FIG. 6 illustrates an embodiment in which the light emitting unit EMU is coupled between the pixel circuit PXC and the second drive power supply VSS, but the light emitting unit EMU may also be coupled between the first drive power supply VDD and the pixel circuit PXC.

A structure of the pixel circuit PXC may be variously changed. For example, the pixel circuit PXC may further include at least one transistor element such as a transistor element for initializing the first node N1 and/or a transistor element for controlling light emission times of the light emitting elements LD or may further include other circuit elements such as a boosting capacitor for boosting a voltage of the first node N1.

In addition, although FIG. 6 illustrates an embodiment in which all the light emitting elements LD constituting each light emitting unit EMU are coupled in parallel, the present disclosure is not limited thereto. In some embodiments, the light emitting unit EMU may include at least one series stage including a plurality of light emitting elements LD coupled in parallel to each other. For example, the light emitting unit EMU may also be configured in a series-parallel mixed structure.

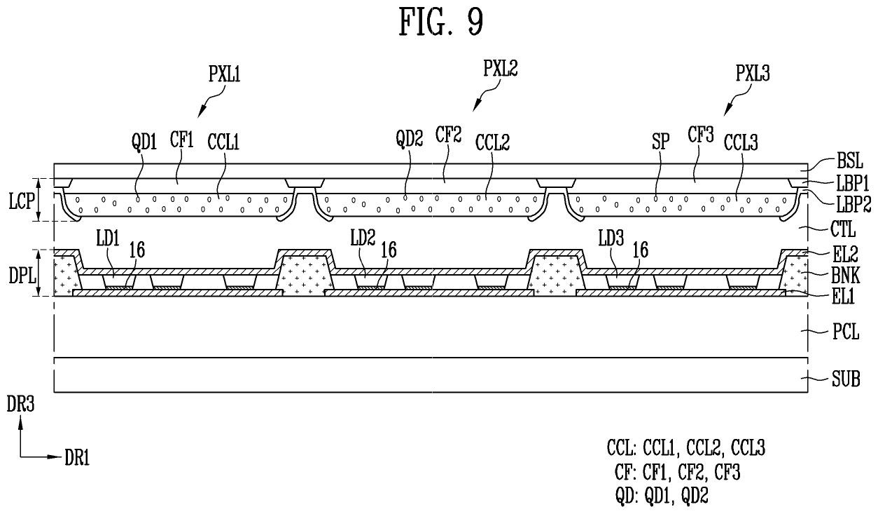

A structure of the pixel PXL applicable to the present disclosure is not limited to the embodiment illustrated in FIG. 8, and the pixel PXL may have various suitable structures. For example, the pixel PXL may also be included in a passive light emitting display device or so on. In this case, the pixel circuit PXC may be omitted, and both ends of the light emitting elements LD included in the light emitting unit EMU may also be coupled to the i^{th} scan line Si, the j^{th} data line Dj, the first power line PL1 coupled to the first drive power supply VDD, the second power line PL2 coupled to the second drive power supply VSS, a set or predetermined control line, and/or the like.

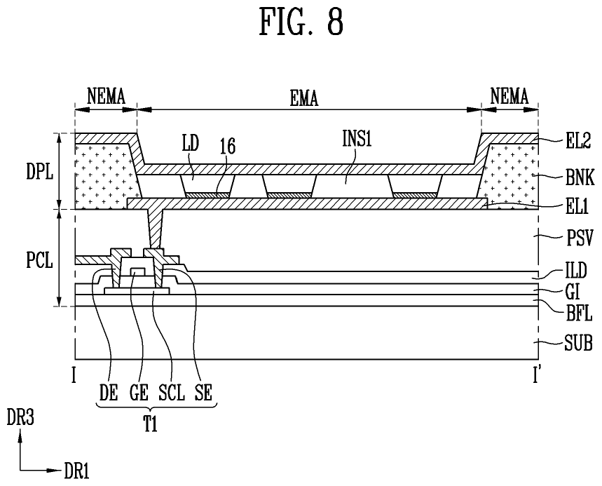

FIG. 7 is a schematic plan view of pixels included in the display device of FIG. 5. FIG. 7 schematically illustrates a structure of pixels PXL1 to PXL3 centering on the light emitting unit EMU of FIG. 6.

Referring to FIG. 7, a first pixel PXL1, a second pixel PXL2, and a third pixel PXL3 may be on a substrate SUB. The first to third pixels PXL1 to PXL3 may constitute one unit pixel.

Each of the first to third pixels PXL1 to PXL3 may include a plurality of light emitting elements LD provided in each of light emitting regions EMA. Here, the light emitting regions EMA may be defined by a bank BNK. For example, the first pixel PXL1 may include first light emitting elements LD1 provided in a first light emitting region EMA1, the second pixel PXL2 may include a second light emitting elements LD2 provided in a second light emitting region EMA2, and the third pixel PXL3 may include third light emitting elements LD3 provided in a third light emitting region EMA3. Each of the first to third light emitting elements LD1 to LD3 may be substantially the same as or similar to the light emitting element LD described with reference to FIGS. 1A to 4B.

In some embodiments, the first to third pixels PXL1 to PXL3 may emit light of different colors. For example, the first pixel PXL1 may be a red pixel that emits red light, the second pixel PXL2 may be a green pixel that emits green light, and the third pixel PXL3 may be a blue pixel that emits blue light. However, the color, type, kind, and/or number of pixels constituting a unit pixel are not limited in particular, and for example, color of light emitted by each pixel may be variously changed. In some embodiments, the first to third pixels PXL1 to PXL3 may emit light of the same (e.g., substantially the same) color. For example, each of the first to third pixels PXL1 to PXL3 may be a blue pixel that emits blue light.

The first to third pixels PXL1 to PXL3 are substantially the same as or similar to each other, and each of the first to third pixels PXL1 to PXL3 is substantially the same as the pixel PXL described with reference to FIG. 6, and thus, the pixel PXL will be described hereinafter on behalf of the first to third pixels PXL1 to PXL3.

FIG. 8 is a cross-sectional view of the pixel taken along line I-I′ of FIG. 7 according to an embodiment.

Although FIG. 8 illustrates that one pixel PXL is simply illustrated so that each electrode is illustrated as an electrode of a single film and a plurality of insulating layers as an insulating layer of a single film, the present disclosure is not limited thereto.

In addition, in one embodiment of the present disclosure, “being formed and/or provided in the same layer” may indicate being formed in the same (e.g., substantially the same) process, and “being formed and/or provided in different layers” may indicate being formed in different processes, unless otherwise stated.

Referring to FIGS. 7 and 8, a pixel circuit layer PCL and a display element layer DPL (or a light emitting element layer) may be sequentially on a substrate SUB. In some embodiments, the pixel circuit layer PCL and the display element layer DPL may be formed on an entire surface of the display region DA of the display device DD (see FIG. 5).

The pixel circuit layer PCL may include a buffer layer BFL, a first transistor T1, and a protective layer PSV. As illustrated in FIG. 8, the buffer layer BFL, the first transistor T1, and the protective layer PSV may be sequentially stacked on the substrate SUB.

The buffer layer BFL may prevent or reduce diffusion of impurities into the transistors T. The buffer layer BFL may be an inorganic insulating film including an inorganic material. The inorganic insulating film may include at least one of metal oxides such as silicon nitride (SiNx), silicon oxide (SiOx), silicon oxynitride (SiON), and/or aluminum oxide (AlOx). The buffer layer BFL may be formed as a single film but may also be formed as multiple films of double films or more. When the buffer layer BFL is forms as the multiple films, each of the layers may be formed of the same material or may be formed of different materials. The buffer layer BFL may be omitted depending on materials and process conditions of the substrate SUB.

A first transistor T1 may be the first transistor T1 described with reference to FIG. 6. A structure of each of the second transistor T2 and the third transistor T3 illustrated in FIG. 6 is substantially the same as or similar to the structure of the first transistor T1, and thus, only the first transistor T1 is illustrated in FIG. 6 for the sake of convenient description.

The first transistor T1 may include a semiconductor pattern SCL, a gate electrode GE, a first terminal DE, and a second terminal SE. The first terminal DE may be one of a source electrode and a drain electrode, and the second terminal SE may be the other electrode. For example, when the first terminal DE is a drain electrode, the second terminal SE may be a source electrode.

The semiconductor pattern SCL may be provided and/or formed on the buffer layer BFL. The semiconductor pattern SCL may include a first contact region in contact with the first terminal DE and a second contact region in contact with the second terminal SE. A region between the first contact region and the second contact region may be a channel region. This channel region may overlap a gate electrode GE of the first transistor T1. The semiconductor pattern SCL may be a semiconductor pattern formed of an oxide semiconductor. However, the present disclosure is not limited thereto, and the semiconductor pattern SCL may also be a semiconductor pattern formed of polysilicon (e.g., polycrystalline silicon), amorphous silicon, and/or the like. The channel region may be a semiconductor pattern that is not doped with impurities, for example, an intrinsic semiconductor. The first contact region and the second contact region may be semiconductor patterns doped with impurities.

The gate insulating layer GI may be provided and/or formed on the semiconductor pattern SCL. The gate insulating layer GI may be an inorganic insulating film including an inorganic material. For example, the gate insulating layer GI may include the same (e.g., substantially the same) material as the buffer layer BFL or may include one or more materials selected from example materials identified as constituent materials of the buffer layer BFL. In some embodiments, the gate insulating layer GI may also be formed of an organic insulating film including an organic material. The gate insulating layer GI may be provided as a single film but may be provided as multiple films of double films or more.

The gate electrode GE may be provided and/or formed on the gate insulating layer GI to correspond to the channel region of the semiconductor pattern SCL. The gate electrode GE may be provided on the gate insulating layer GI to overlap the channel region of the semiconductor pattern SCL. The gate electrode GE may be formed in a single film structure including a single material or a mixture thereof selected from the group consisting of copper (Cu), molybdenum (Mo), tungsten (W), aluminum neodymium (AlNd), titanium (Ti), aluminum (Al), silver (Ag), and an alloy thereof, or may be formed in a double-film structure or a multi-film structure composed of low-resistance materials such as molybdenum (Mo), titanium (Ti), copper (Cu), aluminum (Al), and/or silver (Ag) to reduce wiring resistance.

An interlayer insulating layer ILD may be provided and/or formed on the gate electrode GE. The interlayer insulating layer ILD may include the same (e.g., substantially the same) material as the gate insulating layer GI or may include one or more materials selected from example materials identified as constituent materials of the gate insulating layer GI.

Each of the first terminal DE and the second terminal SE may be provided and/or formed on the interlayer insulating layer ILD and may be in contact with the first contact region and the second contact region of the semiconductor pattern SCL through a contact hole that sequentially penetrates the gate insulating layer GI and the interlayer insulating layer ILD. Each of the first and second terminals DE and SE may include the same (e.g., substantially the same) material as the gate electrode GE or may include one or more materials selected from example materials identified as constituent materials of the gate electrode GE.

In the above-described embodiment, the first and second terminals DE and SE of the first transistor T1 are described as separate electrodes electrically coupled to the semiconductor pattern SCL through a contact hole sequentially penetrating the gate insulating layer GI and the interlayer insulating layer ILD, but the present disclosure is not limited thereto. In some embodiments, the first terminal DE of the first transistor T1 may be the first contact region adjacent to the channel region of the semiconductor pattern SCL, and the second terminal SE of the first transistor T1 may be the second contact region adjacent to the channel region of the corresponding semiconductor pattern SCL. In this case, the second terminal SE of the first transistor T1 may be electrically coupled to the light emitting elements LD of the pixel PXL through a separate connection member such as a bridge electrode.

In FIG. 8, a case in which the first transistor T1 is a thin film transistor having a top gate structure is described as an example, but the present disclosure is not limited thereto, and a structure of the first transistor T1 may be variously changed.

A protective layer PSV may be provided and/or formed on the first transistor T1.

The protective layer PSV may be provided to include an organic insulating film, an inorganic insulating film, or an organic insulating film on the inorganic insulating film. The inorganic insulating film may include at least one of metal oxides such as silicon oxide (SiOx), silicon nitride (SiNx), silicon oxynitride (SiOxNy), and/or aluminum oxide (AlOx). The organic insulating layer may include at least one of, for example, acrylic resin, epoxy resin, phenolic resin, polyamides resin, polyimide resin, unsaturated polyesters resin, poly-phenylene ethers resin, poly-phenylene sulfides resin, and/or benzocyclobutene resin.

The protective layer PSV may include a contact hole exposing the second terminal SE of the first transistor T1.

A display element layer DPL may be provided on the protective layer PSV.

The display element layer DPL may include a first electrode EL1, a bank BNK, light emitting elements LD, a first insulating layer INS1, and a second electrode EL2. The first electrode EL1, the light emitting elements LD, and the second electrode EL2 may be sequentially arranged or formed on the protective layer PSV (or the pixel circuit layer PCL).

The first electrode EL1 (or a pixel electrode) may be arranged or formed on the protective layer PSV. The first electrode EL1 may be correspond to the light emitting region EMA of each pixel PXL illustrated in FIG. 7. In one embodiment, the first electrode EL1 may be an anode.

The first electrode EL1 may be a light guide member (or a reflective member) that guides light emitted from the light emitting elements LD in a third direction DR3 (or an image display direction of a display device). To this end, the first electrode EL1 may be formed of a conductive material (e.g., an electrically conductive material or substance) having a constant reflectance. The conductive material (e.g., the electrically conductive material or substance) may include an opaque metal. The opaque metal may include, for example, silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or an alloy thereof. In some embodiments, the first electrode EL1 may include a transparent conductive material (e.g., a transparent, electrically conductive material or substance). The transparent conductive material (e.g., the transparent, electrically conductive material or substance) may include a conductive oxide such as indium tin oxide (ITO), indium zinc oxide (IZO), zinc oxide (ZnO), indium gallium zinc oxide (IGZO), and/or indium tin zinc oxide (ITZO), a conductive polymer such as poly(3,4-ethylenedioxythiophene) (PEDOT), and/or the like. When the first electrode EL1 includes a transparent conductive material (e.g., the transparent, electrically conductive material or substance), a separate conductive layer may be added which is composed of an opaque metal for reflecting light emitted from the light emitting elements LD in the third direction.

The first electrode EL1 may be in contact with the second terminal SE of the first transistor T1 through a contact hole that penetrates the protective layer PSV and exposes the second terminal SE of the first transistor T1.

The bank BNK may be in a non-light emitting region NEMA of the pixel PXL. The bank BNK may partially overlap an edge of the first electrode EL1 but is not limited thereto. The bank BNK may be a pixel definition film that is formed between the pixels PXL to surround the light emitting region EMA and defines (or partitions) the light emitting region EMA of each pixel PXL. In a step of supplying the light emitting elements LD to the light emitting region EMA, the bank BNK may prevent or reduce flow of a solution mixed with the light emitting elements LD into the light emitting region EMA of the adjacent pixel PXL or may function as a dam structure for controlling a set or certain amount of solution to be supplied to each light emitting region EMA.

The bank BNK may include an insulating material (e.g., an electrically insulating material) including an inorganic material and/or an organic material. For example, the bank BNK may include at least one inorganic layer including various suitable inorganic insulating materials, such as silicon nitride (SiNx) and/or silicon oxide (SiOx). In one or more embodiments, the bank BNK may include at least one layer of an organic film and/or a photoresist film including various suitable organic insulating materials or may also be composed of a single layer or multilayer insulator including a combination of organic and inorganic materials. For example, constituent materials of the bank BNK may be variously changed.

In one embodiment, the bank BNK may include at least one light blocking material and/or a reflective material, thereby reducing a light leakage defect that light leaks between the pixels PXL. In some embodiments, the bank BNK may include a transparent material (or substance). The transparent material may include, for example, polyamides resin, polyimide resin, and/or the like, but the present disclosure is not limited thereto. According to another embodiment, a reflective material layer may be separately provided and/or formed on the bank BNK to further increase efficiency of light emitted from each of the pixels PXL.

Each of the light emitting elements LD may be a light emitting diode having a size as small as a nanoscale to microscale (e.g., a size of nanometers to micrometers) as an example of a micro-sized material having an inorganic crystal structure. Each of the light emitting elements LD may be the light emitting element LD described with reference to FIGS. 1A to 3.

At least two to tens of light emitting elements LD may be aligned and/or provided in the light emitting region EMA, but the number of light emitting elements LD aligned and/or provided in the light emitting region EMA is not limited thereto. In some embodiments, the number of light emitting elements LD arranged and/or provided in the light emitting region EMA may be variously changed.

Each of the light emitting elements LD may emit one selected from color light and white light. In one embodiment, each of the light emitting elements LD may emit blue light in a short wavelength range, but the present disclosure is not limited thereto.

The light emitting element LD may be on the first electrode EL1 so that the metal layer 16 of the light emitting element LD faces the first electrode EL1 or is in contact with the metal layer 16. The light emitting element LD may be arranged so that a height H direction of the light emitting element LD described with reference to FIG. 1A is parallel (e.g., substantially parallel) to the third direction DR3.

In some embodiment, the metal layer 16 of the light emitting element LD may be melted by a laser light (and/or heat) to cause the light emitting element LD to be connected or coupled to the first electrode EL1.

The first insulating layer INS1 (or an insulating layer or a planarization layer) may be provided and/or formed between the light emitting elements LD in the light emitting region EMA. The first insulating layer INS1 may be provided to fill a space between the light emitting elements LD or a free space (or an empty space, a void space) between the light emitting elements LD. In addition, the first insulating layer INS1 may cover the first electrode EL1 exposed between the light emitting elements LD. The first insulating layer INS1 may prevent or reduce contact of a side surface (or the active layer 13 described with reference to FIG. 1A) of the light emitting element LD with another light emitting element LD or another conductive material (for example, another electrically conductive material such as, for example, the second electrode EL2). In addition, the first insulating layer INS1 may cover the first electrode EL1 to reduce occurrence of an electrical short circuit between the first electrode EL1 and the second electrode EL2. To this end, the first insulating layer INS1 may include an insulating material (e.g., an electrically insulating material) including an organic material.

The first insulating layer INS1 may expose one end (for example, the first semiconductor layer 11 described with reference to FIG. 1A) of each of the light emitting elements LD. As illustrated in FIG. 8, a height of the first insulating layer INS1 may be substantially the same as or similar to a height of the light emitting elements LD. However, the height of the first insulating layer INS1 is not limited thereto. For example, as described with reference to FIGS. 2A and 2B, when the light emitting element LD further includes the insulating film 17, the height of the first insulating layer INS1 may be lower than the heights of the light emitting elements LD. As another example, the height of the first insulating layer INS1 may be higher than the heights of the light emitting elements LD, and the first insulating layer INS1 may also include an opening that exposes one end of each of the light emitting elements LD.

In another embodiment, the first insulating layer INS1 may be formed and/or provided by being cured in a process of aligning the light emitting elements LD after a fluid solution (or a mixture) in which the light emitting elements LD are dispersed is supplied (or introduced) to the light emitting region EMA of the pixel PXL. The first insulating layer INS1 may be provided to fill the light emitting region EMA (e.g., an opening of the bank BNK) and may be cured in the light emitting region EMA after alignment of the light emitting elements LD is completed. To this end, the first insulating layer INS1 may include at least one of a photocurable resin including a photopolymerization initiator that is crosslinked and cured by light such as ultraviolet (UV), or a thermosetting polymer resin including a thermal polymerization initiator that initiates a curing reaction by heat. For example, the thermosetting resin may include an epoxy resin composed of an organic material, an amino resin, a phenol resin, a polyester resin, and/or the like. After the light emitting elements LD are aligned (or arranged) in the light emitting region EMA of the pixel PXL, the first insulating layer INS1 may be cured by light (e.g., UV light) and/or heat. Accordingly, the first insulating layer INS1 may stably fix the light emitting elements LD and prevent or reduce separation of the light emitting elements LD.

In one embodiment, the first insulating layer INS1 may also include light scattering particles that scatter light (for example, light reflected by the first electrode EL1) emitted from the light emitting elements LD. The light scattering particles may form an optical interface with a base material (for example, a transparent organic material) constituting the first insulating layer INS1. Light extraction efficiency may be increased by the first insulating layer INS1 including the light scattering particles. The light scattering particles may be dispersedly in the first insulating layer INS1, and, in one or more embodiments, may also form a separate light scattering layer.

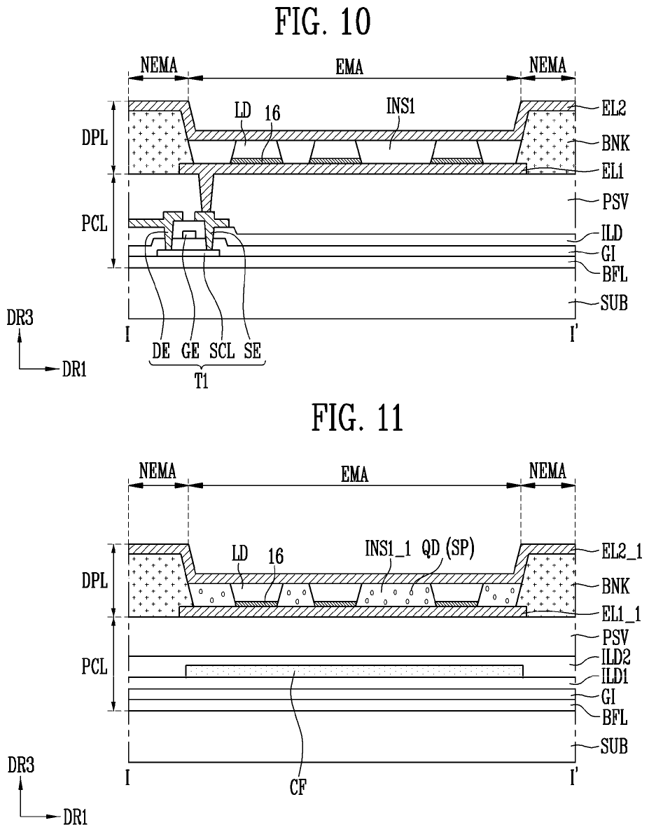

In one embodiment, the first insulating layer INS1 may further include color conversion particles corresponding to a set or specific color. The color conversion particles may convert light of a first color emitted from the light emitting elements LD into light of a second color (or a set or specific color). The color conversion particles will be further described below with reference to FIG. 9.

The second electrode EL2 (or a common electrode) may be provided and/or formed on the light emitting elements LD and the first insulating layer INS1. The second electrode EL2 may be provided or arranged on the bank BNK and may be provided on an entire surface of the substrate SUB. The second electrode EL2 may be a common layer commonly provided to the pixel PXL and pixels (for example, the first to third pixels PXL1 to PXL3 illustrated in FIG. 7) adjacent thereto. In one embodiment, the second electrode EL2 may be a cathode. The second electrode EL2 may be coupled to the second drive power supply VSS (see FIG. 6) so that a voltage of the second drive power supply VSS may be transmitted to the second electrode EL2.

The second electrode EL2 may be formed of various suitable transparent conductive materials (e.g., suitable transparent, electrically conductive materials or substances) so that light emitted from each of the light emitting elements LD travels in the third direction DR3 without loss (e.g., substantially without loss). For example, the second electrode EL2 may include at least one of various suitable transparent conductive materials (e.g., suitable transparent, electrically conductive materials or substances) including indium tin oxide (ITO), indium zinc oxide (IZO), zinc oxide (ZnO), indium gallium zinc oxide (IGZO), indium tin zinc oxide (ITZO), and/or the like, and may be substantially transparent or translucent to satisfy a set or predetermined light transmission (or transmittance). However, a material of the second electrode EL2 is not limited to the above-described embodiment.

In some embodiments, an encapsulation layer may be provided and/or formed on the second electrode EL2. The encapsulation layer may be provided to include an organic insulating film, an inorganic insulating film, or an organic insulating film on the inorganic insulating film. The encapsulation layer may be formed of a transparent insulating material (e.g., a transparent, electrically insulating material) to minimize or reduce loss of light traveling in the third direction DR3. The encapsulation layer may be designed to have a thickness of a set or certain level or more, thereby reducing a step difference caused by configuration elements thereunder. The second electrode EL2 may be provided on the entire surface of the substrate SUB, thereby preventing or reducing penetration of impurities into the substrate and serving as a buffer against external impact.

As described above, the metal layer 16 (and the other end or the second semiconductor layer 15 (see FIG. 1A)) of each of the light emitting elements LD may be at a lower end in the third direction DR3, and one end (or the first semiconductor layer 11 (see FIG. 1A)) of each of the light emitting elements LD may be at an upper end in the third direction DR3. For example, each of the light emitting elements LD may be aligned in the third direction DR3. Accordingly, each of the light emitting elements LD may emit light in all regions where the active layer 12 (see FIG. 1A) is located. For example, the light that is emitted from the active layer 13 of each of the light emitting elements LD and directed (e.g., directed in a direction opposite to the third direction DR3) to the other end of the corresponding light emitting element LD may be reflected by the first electrode EL1 and travels in a desirable direction (e.g., an image display direction of the display device). In addition, the light that is emitted from the active layer 13 of each of the light emitting elements LD and directed (e.g., directed in the third direction DR3) toward one end of the corresponding light emitting element LD may pass through the second electrode EL2 as it is and travels in the image display direction of the display device. Accordingly, the amount (or intensity) of the light that is emitted from each of the light emitting elements LD and travels in the image display direction of the display device may be increased, and thus, light emission efficiency of the pixel PXL may be increased.

In addition, other configuration elements except for the first insulating layer INS1 and the light emitting elements LD are not provided between the first electrode EL1 and the second electrode EL2, and thereby, the light emitted from the light emitting elements LD may travel in the image display direction of the display device without being dispersed by the other configuration elements. Accordingly, the amount (or intensity) of light traveling in the image display direction of the display device may be further increased, and thus, the light emission efficiency of the pixel PXL may be further increased.

Additionally, the light emitting elements LD are aligned in a vertical direction between the first electrode EL1 and the second electrode EL2 spaced apart from each other in a vertical direction, and thereby, an alignment area of the light emitting elements LD may be obtained more in the light emitting region EMA of the pixel PXL. For example, a support member, which guides the light emitted from the light emitting elements LD in a target direction, for example, a reflective partition wall and/or the like may be omitted, and thus, a space efficiency of the light emitting region EMA may be increased. Accordingly, spatial constraints between configuration elements included in the pixel PXL may be reduced, resulting in easy implementation of a high-resolution display device.

FIG. 9 is a cross-sectional view of the pixels illustrated in FIG. 7.

Referring to FIGS. 7 to 9, an upper substrate may also be further on the second electrode EL2.

The upper substrate may be provided on a display element layer DPL to cover a display region (see “DA” of FIG. 3) in which the pixels (for example, the first to third pixels PXL1 to PXL3) are arranged. The upper substrate may be composed of an encapsulation substrate (or a thin film encapsulation layer) of the display device and/or a window member thereof. An intermediate layer CTL may be provided between the upper substrate and the display element layer DPL.

The intermediate layer CTL may be a transparent adhesive layer (or an adhesive layer), which reinforces an adhesive force between the display element layer DPL and the upper substrate, for example, an optically clear adhesive layer, but the present disclosure is not limited thereto. In some embodiments, the intermediate layer CTL may be a refractive index conversion layer for improving a light emission luminance of each of the pixels PXL by converting a refractive index of light that is emitted from the light emitting elements LD and travels to the upper substrate.

The upper substrate may include a base layer BSL and a light conversion pattern layer LCP.

The base layer BSL may be a rigid substrate and/or a flexible substrate, and a material and/or a physical property thereof is not limited in particular. The base layer BSL may be formed of the same (e.g., substantially the same) material as the substrate SUB or may also be formed of a material different from a material of the substrate SUB.

The light conversion pattern layer LCP may be on one surface of the base layer BSL to face the pixels (for example, the first to third pixels PXL1 to PXL3) of the substrate SUB. The light conversion pattern layer LCP may include a color conversion layer CCL corresponding to a set or predetermined color and a color filter CF.

The color conversion layer CCL may include color conversion particles QD corresponding to a set or specific color. One color conversion layer CCL may be on one surface of the base layer BSL to face one pixel (or one sub-pixel) and may include the color conversion particles QD for converting light of a set or specific color emitted from the light emitting elements in one pixel into light of a set or specific color. For example, when the first pixel PXL1 is a red pixel, the first color conversion layer CCL1 may include red quantum dot color conversion particles QD1 that convert the light emitted from the first light emitting elements LD1 into red light. As another example, when the second light emitting pixel PXL2 is a green pixel, the second color conversion layer CCL2 may include green quantum dot color conversion particles QD2 that convert the light emitted from the second light emitting elements LD2 into green light. As another example, when the third pixel PXL3 is a blue pixel, the third color conversion layer CCL3 may also include blue quantum dot color conversion particles QD3 that convert the light emitted from the third light emitting element LD3 into blue light. In contrast to the foregoing, when the third light emitting elements LD3 emit blue light, the third color conversion layer CCL3 may also include light scattering particles SP that scatter light emitted from the third light emitting elements LD3 instead of the blue quantum dot color conversion particles.

In some embodiment, when the one pixel is a blue pixel (or a blue sub-pixel), the color conversion layer CCL may also include the light scattering particles SP instead of the color conversion particles QD. For example, when the third light emitting elements LD3 emit blue light, the third color conversion layer CCL3 (or the light scattering layer) may also include the light scattering particles SP. The above-described light scattering layer may also be omitted in some embodiments. According to another embodiment, when the third pixel PXL3 is a blue pixel (or a blue sub-pixel), a transparent polymer may also be provided instead of the third color conversion layer CCL3.

The color filter CF may be between the color conversion layer CCL and the base layer BSL and may include a color filter material that transmits light of a set or specific color converted by the color conversion layer CCL. The color filter CF may include a red color filter, a green color filter, and a blue color filter. For example, when the first pixel PXL1 is a red pixel, a first color filter CF1 that transmits red light may be on the first pixel PXL1. When the second pixel PXL2 is a green pixel, a second color filter CF2 that transmits green light may be on the second pixel PXL2. When the third pixel PXL3 is a blue pixel, a third color filter CF3 that transmits blue light may be on the third pixel PXL3.

A first light blocking pattern LBP1 may be between the color filter CF corresponding to one pixel and a color filter corresponding to a pixel adjacent to the one pixel. For example, the first light blocking pattern LBP1 may be between the first color filter CF1 and the second color filter CF2 or between the second color filter CF2 and the third color filter CF3. The first light blocking pattern LBP1 may be provided on the base layer BSL to overlap the bank BNK. In some embodiments, the first light blocking pattern LBP1 may be provided in the form of a multifilm in which at least two color filters overlap which selectively transmit light of different colors among a red color filter, a green color filter, and a blue color filter. For example, the first light blocking pattern LBP1 may also be provided in the form of a structure that includes a red color filter, a green color filter on the red color filter to overlap the red color filter, and a blue color filter on the green color filter to overlap the green color filter. In one or more embodiments, the first light blocking pattern LBP1 may be provided in the form of a structure in which a red color filter, a green color filter, and a blue color filter are sequentially stacked. In this case, the red color filter, the green color filter, and the blue color filter may be used as the first light blocking pattern LBP1 that blocks transmission of light in the non-light emitting region NEMA (see FIG. 8).

In some embodiments, a second light blocking pattern LBP2 may be on the first light blocking pattern LBP1. The first light blocking pattern LBP1 and the second light blocking pattern LBP2 may include the same (e.g., substantially the same) material. For example, the first light blocking pattern LBP1 and the second light blocking pattern LBP2 may be a black matrix.

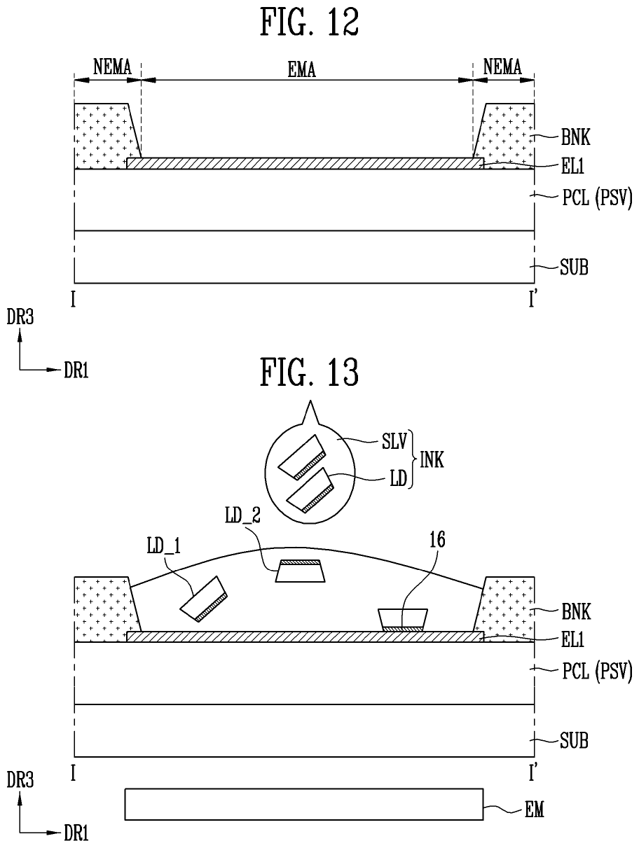

FIG. 10 is a cross-sectional view taken along line I-I′ of the pixel in FIG. 7, according to another embodiment. FIG. 10 illustrates a cross-section corresponding the cross-section of FIG. 8.

Referring to FIGS. 7, 8, and 10, the embodiment of FIG. 8 is different from the embodiment of FIG. 10 in that the light emitting elements LD described with reference to FIGS. 1A to 3 are applied to the embodiment of FIG. 8 and the light emitting elements LD described with reference to FIGS. 4A and 4B are applied to the embodiment of FIG. 10. The embodiment of FIG. 10 is substantially the same as the embodiment of FIG. 8 except for shapes of the light emitting elements LD, and thus, repetitive descriptions thereof will not be repeated here.

As described with reference to FIG. 8, the metal layer 16 (and the other end or the second semiconductor layer 15 (see FIG. 4A) of each of the light emitting elements LD may be at a lower end in the third direction DR3, and one end (or the first semiconductor layer 11 (see FIG. 4A) of each of the light emitting elements LD may be at an upper end in the third direction DR3. For example, each of the light emitting elements LD may be aligned in the third direction DR3.

Because an area of the metal layer 16 of each of the light emitting elements LD is relatively large, when the light emitting elements LD are supplied on the substrate SUB, a ferromagnetic material and/or a quasi-ferromagnetic material included in the metal layer 16 may help more to arrange the light emitting elements LD on the substrate SUB so that metal layer 16 faces the substrate. Accordingly, a probability that the light emitting elements LD are arranged or aligned in a desired position on the substrate SUB may be increased, and misarrangement (or misalignment) of the light emitting elements LD may be further reduced.

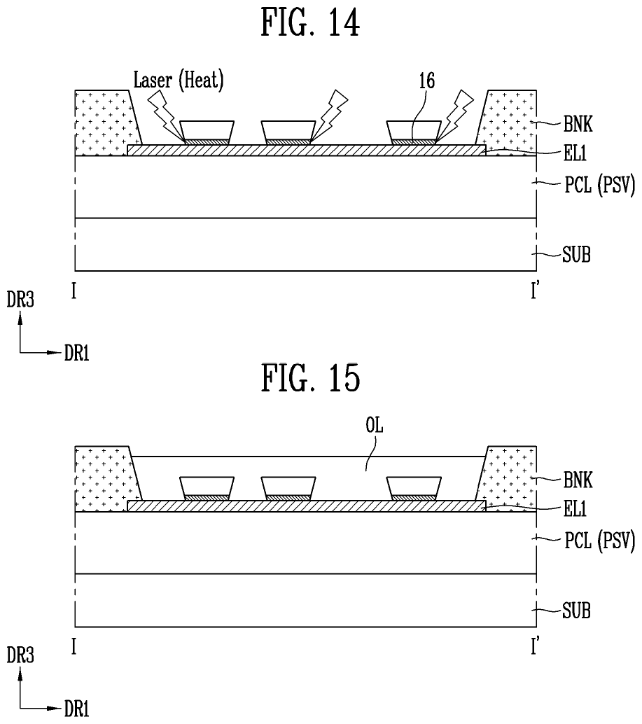

FIG. 11 is a cross-sectional view taken along line I-I′ of the pixel in FIG. 7, according to another embodiment. FIG. 11 illustrates a cross section corresponding to the cross section of FIG. 8.

Referring to FIGS. 7, 8, and 11, light (or an image) may travel or may be displayed in the third direction DR3 in the embodiment of FIG. 8, and light may travel or may be displayed in a direction opposite to the third direction DR3 in the embodiment of FIG. 10. To this end, a first electrode EL1_1 and a second electrode EL2_1 may be provided, and a first insulating layer INS1_1 and a color filter CF may be further provided.

Except for the first electrode EL1_1, the second electrode EL2_1, a first insulating layer INS1_1, and a color filter CF, the embodiment of FIG. 11 is substantially the same as or similar to the embodiment of FIG. 8, and thus, repetitive description thereof will not be repeated here.

The first electrode EL1_1 may be formed of a transparent conductive material (e.g., a transparent, electrically conductive material or substance) to transmit light emitted from each of the light emitting elements LD without loss (or substantially without loss). The transparent conductive material (e.g., the transparent, electrically conductive material or substance) may include a conductive oxide such as indium tin oxide (ITO), indium zinc oxide (IZO), zinc oxide (ZnO), indium gallium zinc oxide (IGZO), and/or indium tin zinc oxide (ITZO), and/or a conductive polymer such as poly(3,4-ethylenedioxythiophene) (PEDOT).

The first insulating layer INS1_1 may be provided to fill a space between the light emitting elements LD. The light emitting elements LD may be the light emitting elements LD described with reference to FIGS. 4A and 4B as well as the light emitting elements LD described with reference to FIGS. 1A to 3.

The first insulating layer INS1_1 may include color conversion particles QD corresponding to a set or specific color. The first insulating layer INS1_1 may include color conversion particles QD that convert light of a first color emitted from the light emitting elements LD on the pixel PXL into light of a second color (or a set or specific color). As described with reference to FIG. 9, when the pixel PXL is a red pixel, the first insulating layer INS1_1 may include red quantum dot color conversion particles QD that convert the light emitted from the light emitting elements LD into red light. When the pixel PXL is a green pixel, the first insulating layer INS1_1 may include green quantum dot color conversion particles QD that convert the light emitted from the light emitting elements LD into green light. As another example, when the pixel PXL is a blue pixel, the first insulating layer INS1_1 may include blue quantum dot color conversion particles QD that convert the light emitted from the light emitting elements LD into blue light or may also include light scattering particles SP that scatter the light emitted from the light emitting elements LD.

The second electrode EL2_1 (or a common electrode) may be provided and/or formed on the light emitting elements LD and the first insulating layer INS1. The second electrode EL2_1 may be provided or arranged on the bank BNK and may be provided on the entire surface of the substrate SUB.

The second electrode EL2_1 may be a guide member that guides light (for example, light of a second color) emitted from the first insulating layer INS1_1 (and the light emitting elements LD) in an image display direction of a display device (a lower direction of the substrate SUB). To this end, the second electrode EL2_1 may be formed of a conductive material (e.g., an electrically conductive material or substance) having a constant reflectance. The conductive material (e.g., the electrically conductive material or substance) may include an opaque metal.

In some embodiments, an encapsulation layer may be provided and/or formed on the second electrode EL2_1 as described with reference to FIG. 8,

The color filter CF may be provided between a first interlayer insulating layer ILD1 and a second interlayer insulating layer ILD2 to correspond to the light emitting region EMA. Here, each of the first interlayer insulating layer ILD1 and the second interlayer insulating layer ILD2 may be substantially the same as or similar to the interlayer insulating layer ILD described with reference to FIG. 8. The color filter CF may selectively transmit light that is emitted through the first insulating layer INS1 and travels toward the substrate SUB. As described with reference to FIG. 9, the color filter CF may include a red color filter, a green color filter, and a blue color filter.

Although FIG. 11 illustrates that the color filter CF is provided between the first interlayer insulating layer ILD1 and the second interlayer insulating layer ILD2, a position of the color filter CF is not limited thereto. For example, the color filter CF may be on a certain layer of the pixel circuit layer PCL under the first electrode EL1_1. For example, the color filter CF may also be on the second interlayer insulating layer ILD2.

As described above, the pixel PXL (or the display device) may also have not only a front surface light emission structure but also a rear surface light emission structure. For example, in the embodiment of FIG. 11, the color filter CF is provided in the pixel circuit layer PCL, and the color conversion particles QD (or the light scattering particles SP) are provided inside the first insulating layer INS1_1, and thus, a display device may be made thinner and a fabrication process of the display device may be more simplified.

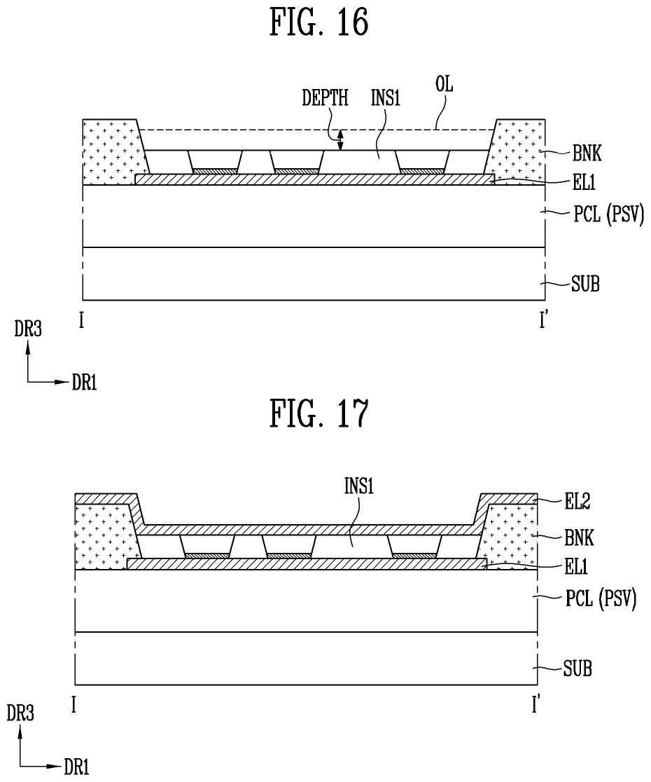

Hereinafter, a method of fabricating a display device will be described with reference to FIGS. 12 to 17.

FIGS. 12 to 17 are schematic cross-sectional views illustrating a method of fabricating a display device according to an embodiment of the present disclosure. FIGS. 12 to 17 are diagrams corresponding to FIG. 8. For the sake of convenient description, FIGS. 12 to 17 schematically illustrate a display device DD (see FIG. 5) (or the pixel PXL) with centering on a light emitting unit EMU (see FIG. 6) (or the display element layer DPL).

First, referring to FIGS. 5, 7, 8, and 12, the first electrode EL1 may be formed on the pixel circuit layer PCL (or the protective layer PSV and the substrate SUB). The first electrode EL1 may correspond to the light emitting region EMA of each of the pixels PXL illustrated in FIG. 7.

The bank BNK may be formed on the pixel circuit layer PCL (or the substrate SUB). The bank BNK may correspond to the non-light emitting region NEMA. The light emitting region EMA may be defined by the bank BNK, and the first electrode EL1 may be exposed through an opening of the bank BNK.

Referring to FIGS. 12 and 13, a solvent SLV and ink INK including light emitting elements LD included (or dispersed) in the solvent SLV may be supplied to the light emitting region EMA of each of the pixels PXL. For example, the ink INK may be supplied to the light emitting region EMA of each of the pixels PXL through an inkjet printing method and/or a slit coating method.

As described with reference to FIGS. 1A to 3 (or FIGS. 4A and 4B), the light emitting element LD may have a truncated pyramid shape or a truncated cone shape, and an area ratio between an upper surface and a lower surface of the light emitting element LD may be 0.25 or more, and a length ratio between a height (or a thickness) of the light emitting element LD and a length of the longest side of the lower surface may be 0.5 or less. Accordingly, most of the light emitting elements LD (for example, a light emitting element LD_1 having a side surface facing the first electrode EL1) may be arranged or aligned on the first electrode EL1 so that a metal layer 16 thereof faces or is in contact with the first electrode EL1 as a result of a force of gravity.

In one or more embodiments, an electromagnet EM may be under the substrate SUB. The electromagnet EM may be outside the display device but is not limited thereto.

The electromagnet EM may form a magnetic field under the substrate SUB when the light emitting element LD is supplied or aligned. In this case, the light emitting element LD may be on the substrate SUB so that a metal layer 16 thereof faces the substrate while a ferromagnetic material and/or a quasi-ferromagnetic material included in the metal layer 16 of the light emitting element LD is attracted to the electromagnet EM. For example, a light emitting element LD_2 supplied so that the metal layer 16 faces the first electrode EL1 may be rotated 180 degrees by the electromagnet EM to make the metal layer 16 face the substrate, thereby being on the substrate SUB.

In one or more embodiments, most of the light emitting elements LD (for example, the light emitting element LD_2 having the metal layer 16 facing the first electrode EL1) may be arranged or aligned on the first electrode EL1 so that the metal layer 16 may naturally face or be in contact with the first electrode EL1 due to the truncated pyramid shape or the truncated cone shape of the light emitting element LD and due to the force of gravity and/or the like. In addition, the light emitting element LD may be on the substrate so that the metal layer 16 of the light emitting element LD faces the substrate with assistance from the electromagnet EM. Therefore, most of the light emitting elements LD are arranged or aligned in a suitable or desired position on the substrate SUB, that is, so that the metal layer 16 faces or is in contact with the first electrode EL1, and thus, alignment efficiency of the elements LD may be greatly increased. In other words, the number and ratio of the reverse light emitting elements LDr (see FIG. 6) may be reduced.

After the light emitting elements LD are aligned, the solvent SLV is volatilized or removed in another way, and thereby, the light emitting elements LD may be stably on the first electrode EL1.

Thereafter, as illustrated in FIG. 14, a laser light (for example, from an infrared laser) and/or heat may be applied to the metal layer 16 of each of the light emitting elements LD. In this case, while a fusible alloy and/or a eutectic alloy included in the metal layer 16 of each of the light emitting elements LD is melted, each of the light emitting elements LD may be coupled or connected to the first electrode EL1. The metal layer 16 stably fixes the light emitting elements LD, thereby separation of each of the light emitting elements LD from the metal layer 16 may be prevented or reduced.

Thereafter, as illustrated in FIG. 15, an organic insulating layer OL may be coated or formed on the first electrode EL1. The organic insulating layer OL may be provided only inside the light emitting region EMA but is not limited thereto.

The organic insulating layer OL may include an organic insulating material and may fill a space between the light emitting elements LD or between the light emitting elements LD in the light emitting region EMA. In some embodiments, the organic insulating layer OL may also cover the light emitting elements LD. The organic insulating layer OL may planarize a support surface of the second electrode EL2 (see FIG. 16).

Thereafter, as illustrated in FIG. 16, a part of the organic insulating layer OL may be removed through an etching process to expose one region (for example, one end) of each of the light emitting elements LD.

For example, the organic insulating layer OL may be etched by a set or predetermined depth DEPTH so that upper surfaces of the light emitting elements LD are exposed through a dry etching process. In this case, the first insulating layer INS1 may be formed to fill a space between the light emitting elements LD and expose the upper surfaces of the light emitting elements LD from the organic insulating layer OL.

Thereafter, the second electrode EL2 (or a common electrode) may be formed on the light emitting elements LD and the first insulating layer INS1. The second electrode EL2 may also be provided or arranged on the bank BNK, and the second electrode EL2 may be formed on the entire surface of the substrate SUB.

Through the above-described process, the pixel PXL (or a display device) according to the embodiment of FIG. 8 may be fabricated.

In some embodiments, the color conversion layer CCL (see FIG. 9) may also be further formed on the second electrode EL2. Through the above-described process, the pixels PXL1 to PXL3 (or a display device) according to the embodiment of FIG. 9 may be fabricated.

As described with reference to FIGS. 12 to 17, the light emitting element LD may be on the substrate so that the metal layer 16 of the light emitting element LD faces the substrate by a truncated pyramid shape or a truncated cone shape of the light emitting element LD, and with assistance from a ferromagnetic material and/or a quasi-ferromagnetic material (and the electromagnet EM) of the metal layer 16 of the light emitting element LD. Accordingly, alignment efficiency of the light emitting element LD may be greatly increased.

In addition, by applying a laser light and/or heat to the metal layer 16 of the light emitting element LD, a fusible alloy and/or a eutectic alloy included in the metal layer 16 of the light emitting element LD may be melted to stably couple or connect the light emitting element LD to the electrode EL1.

Although the above description has been made with reference to example embodiments of the present disclosure, those skilled in the art or those having ordinary skill in the relevant technical field will understand that the subject matter of the present disclosure may be variously modified and changed without departing from the spirit and technical scope of the present disclosure as defined by the appended claims, and equivalents thereof.

Accordingly, the technical scope of the present disclosure is not limited to the content described in the detailed description of the specification but should be determined by the appended claims, and equivalents thereof.

What is claimed is:

1. A display device comprising:
a substrate;
a first electrode on the substrate;
a plurality of light emitting elements on the first electrode; and
a second electrode on the plurality of light emitting elements,
wherein an area of a first surface of each of the plurality of light emitting elements in contact with the first electrode is different from an area of a second surface of each of the plurality of light emitting elements in contact with the second electrode, and
wherein each of the plurality of light emitting elements comprises a metal layer in contact with the first electrode and comprising a fusible alloy and/or a eutectic alloy.

2. The display device of claim 1, wherein the area of the first surface is smaller than the area of the second surface, and an area ratio between the first surface and the second surface of each of the plurality of light emitting elements is 0.25 or more.

3. The display device of claim 1, wherein a length ratio between a height of each of the plurality of light emitting elements and a length of a longest side of the second surface is 0.5 or less.

4. The display device of claim 3, wherein the length of the longest side of the second surface is approximately 10 nm to approximately 10 μm.

5. The display device of claim 3, wherein each of the plurality of light emitting elements has a truncated pyramid shape or a truncated cone shape.

6. The display device of claim 5, wherein each of the plurality of light emitting elements further comprises:
a first semiconductor layer in contact with the second electrode;
a second semiconductor layer in contact with the metal layer; and
an active layer between the first semiconductor layer and the second semiconductor layer.

7. The display device of claim 6, wherein the first semiconductor layer is an n-type semiconductor layer and the second semiconductor layer is a p-type semiconductor layer.

8. The display device of claim 6, wherein each of the plurality of light emitting elements further comprises:
a third semiconductor layer between the first semiconductor layer and the active layer; and
a fourth semiconductor layer between the second semiconductor layer and the active layer.

9. The display device of claim 6, wherein each of the plurality of light emitting elements further comprises:
an insulating film that surrounds an outer peripheral surface of a light emitting stack comprising the first semiconductor layer, the second semiconductor layer, and the active layer, and exposes the first surface and the second surface.

10. The display device of claim 1, wherein:
a melting point of the fusible alloy and/or the eutectic alloy is approximately 200° C. to approximately 300° C.

11. The display device of claim 1, wherein the metal layer comprises one selected from a group consisting of an alloy including 32.5% of bismuth (Bi), 16.5% of tin (Sn), 51% of indium (In); an alloy including less than 1.5% of Bi, 9.5 to 10.5% of Sn, 21 to 22% of In, 68 to 69% of gallium (Ga), and less than 1.5% of antimony (Sb); an alloy including 49% of Bi, 18% of lead (Pb), 12% of Sn, and 21% of In; an alloy including 44.7% of Bi, 22.6% of Pb, 8.3% of Sn, 19.1% of In, and 5.3% of cadmium (Cd); an alloy including 50% of Bi, 25% of Pb, and 25% of Sn; an alloy including 50% of Bi, 26.7% of Pb, 13.3% of Sn, and 10% of Cd; 42.5% of Bi, 37.7% of Pb, 11.3% of Sn, and 8.5% of Cd; 50% of Bi, 26.7% of Pb, 13.3% of Sn, and 10% of Cd; an alloy including 49.5% of Bi, 27.3% of Pb, 13.1% of Sn, and 10.1% of Cd; an alloy including 66.3% of In, and 33.7% of Bi; 56% of Bi, 30% of Sn, and 14% of In; an alloy including 50% of Bi, 30% Pb, and 20% of SN; an alloy including 52.5% of Bi, 32.0% of Pb, and 15.5% of Sn; an alloy including 52% of Bi, 32.0% of Pb, and 16% of Sn; an alloy including 50.0% of Bi, 31.2% of Pb, and 18.8% of Sn; an alloy including 55.5% of Bi, and 44.5% of Pb; 58% of Bi, and 42% of Sn; 57% of Bi, and 43% of Sn; an alloy including 62.3% of Sn, and 37.7% of Pb; an alloy including 63.0% of Sn, and 37.0% of Pb; an alloy including 91.0% of Sn, and 9.0% of Sn; and an alloy including 92.0% of Sn, and 8.0% of Zn.

12. The display device of claim 1, wherein the metal layer further comprises a magnetic material.

13. The display device of claim 12, wherein the magnetic material comprises a ferromagnetic material and/or a quasi-ferrimagnetic material.

14. The display device of claim 13, wherein the magnetic material comprises an alloy including 80% of nickel and 20% of iron, and/or a terbium-iron alloy.

15. The display device of claim 1, further comprising:
an insulating layer that fills a free space between the plurality of light emitting elements and exposes one surface of each of the plurality of light emitting elements in contact with the second electrode.

16. The display device of claim 15, wherein the insulating layer comprises light scattering particles that scatter light emitted from the plurality of light emitting elements.

17. The display device of claim 15, wherein the insulating layer comprises color conversion particles that absorb a light of a first color emitted from the plurality of light emitting elements and emit a light of a second color.

18. The display device of claim 15, further comprising:
a bank on the substrate to define a light emitting region,
wherein the first electrode and the plurality of light emitting elements are provided in the light emitting region.

19. The display device of claim 18, wherein the bank comprises a reflective material and increases efficiency of light emitted from the light emitting region.

20. The display device of claim 1, further comprising:
a light conversion pattern layer on the second electrode to absorb a light emitted from the plurality of light emitting elements and to emit red light or green light.

21. The display device of claim 1, further comprising:
a color filter under the first electrode.

22. The display device of claim 1, wherein the first electrode comprises a transparent conductive material, and the second electrode comprises an opaque metal.

23. The display device of claim 1, wherein the area of the first surface is larger than the area of the second surface, and an area ratio between the first surface and the second surface of each of the plurality of light emitting elements is 4 or less.

24. The display device of claim 23, wherein a length ratio between a height of each of the plurality of light emitting elements and a length of a longest side of the first surface is 0.5 or less.

25. A method of fabricating a display device, the method comprising:
forming a first electrode on a substrate;
supplying ink comprising a plurality of light emitting elements dispersed in a solvent onto the first electrode;
aligning the plurality of light emitting elements; and
forming a second electrode on the plurality of light emitting elements,
wherein an area of a first surface of each of the plurality of light emitting elements in contact with the first electrode is different from an area of a second surface of each of the plurality of light emitting elements in contact with the second electrode, and
wherein each of the plurality of light emitting elements comprises a metal layer in contact with the first electrode and comprising a eutectic solder and/or a fusible alloy.

26. The method of claim 25, wherein the ink is supplied onto the first electrode through an inkjet printing technique.

27. The method of claim 25, wherein the aligning of the plurality of light emitting elements comprises coupling the plurality of light emitting elements to the first electrode by applying a laser light to the metal layer of each of the plurality of light emitting elements.

28. The method of claim 27, wherein the aligning of the plurality of light emitting elements further comprises aligning the plurality of light emitting elements by applying a magnetic field under the first electrode before the plurality of light emitting elements are coupled to the first electrode, and
wherein the metal layer further comprises a magnetic material.

29. The method of claim 25, further comprising:
forming a planarization layer on the first electrode to fill a space between the plurality of light emitting elements before the second electrode is formed.

30. The method of claim 29, wherein the forming of the planarization layer on the first electrode comprises:
coating an organic insulating layer on the first electrode; and
etching the organic insulating layer to form the planarization layer that exposes the second surfaces of the plurality of light emitting elements.
